(19) United States
(12) Patent Application Publication
(10) Pub. No.: US 2025/0062287 A1
(43) Pub. Date: Feb. 20, 2025

(54) SEMICONDUCTOR PACKAGE INCLUDING SEMICONDUCTOR DIE STACKS

(71) Applicant: Samsung Electronics Co., Ltd., Suwon-si (KR)

(72) Inventor: Kwangyong Lee, Suwon-si (KR)

(21) Appl. No.: 18/670,352

(22) Filed: May 21, 2024

(30) Foreign Application Priority Data
Aug. 16, 2023 (KR) 10-2023-0107097

(51) Int. Cl. H01L 25/065

(52) U.S. Cl. CPC H01L 25/0657; H01L 2225/06506

(57) ABSTRACT

A semiconductor package includes a lower semiconductor die stack in which lower semiconductor dies are stacked vertically in a stepwise manner to extend in a first horizontal direction, an upper semiconductor die stack in which upper semiconductor dies are stacked vertically on the lower semiconductor die stack in a stepwise manner to extend in a first reverse horizontal direction, a wiring structure above the upper semiconductor die stack, and bonding wire groups connecting the lower semiconductor dies and the upper semiconductor dies to the wiring structure. The bonding wire groups include a first bonding wire group that includes bonding wires that connect a first plurality of semiconductor dies of the upper and lower semiconductor dies to the wiring structure. The bonding wire group includes a first curved wire connecting a second plurality of semiconductor dies of the first plurality of semiconductor dies, a first upward wire connected to the first curved wire, a first inclined wire connected to the first upward wire, and a second upward wire to connect the first inclined wire to the wiring structure.

### CROSS-REFERENCE TO RELATED APPLICATION

This application is based on and claims priority under 35 U.S.C. § 119 to Korean Patent Application No. 10-2023-0107097, filed on Aug. 16, 2023, in the Korean Intellectual Property Office, the disclosure of which is incorporated by reference herein in its entirety.

### BACKGROUND

The inventive concept relates to a semiconductor package, and more particularly, to a semiconductor package including semiconductor die stacks.

Electronic products are becoming smaller in size while satisfying high performance and high capacity demands. Semiconductor packages used in the electronic products are also required to be made small. Accordingly, it is necessary to stack semiconductor dies included in a semiconductor package and to easily connect the semiconductor dies with bonding wires.

### SUMMARY

The inventive concept relates to a semiconductor package including a plurality of semiconductor die stacks, and a bonding wire group capable of easily connecting the semiconductor die stacks to a wiring structure.

According to an aspect of the inventive concept, there is provided a semiconductor package including a lower semiconductor die stack in which a plurality of lower semiconductor dies are stacked in a stepwise manner to extend in a first horizontal direction, an upper semiconductor die stack in which a plurality of upper semiconductor dies are stacked vertically on the lower semiconductor die stack in a stepwise manner to extend in a first reverse horizontal direction (−X direction) opposite to the first horizontal direction, a wiring structure positioned above the upper semiconductor die stack, and bonding wire groups connecting the lower semiconductor dies and the upper semiconductor dies to the wiring structure.

The bonding wire groups include a first bonding wire group connecting a first plurality of semiconductor dies selected from the lower semiconductor dies and the upper semiconductor dies to the wiring structure. The first bonding wire group includes a first bonding portion including a first curved wire connecting a second plurality of semiconductor dies of the first plurality semiconductor dies, a first upward wire connected to the first curved wire and extending toward the wiring structure, a first inclined wire connected to the first upward wire, and a second upward wire extending toward the wiring structure to connect the first inclined wire to the wiring structure.

According to another aspect of the inventive concept, there is provided a semiconductor package including a lower semiconductor die stack in which a plurality of lower semiconductor dies are stacked in a stepwise manner to extend in a first horizontal direction, an upper semiconductor die stack in which a plurality of upper semiconductor dies are stacked on the lower semiconductor die stack in a stepwise manner to extend in a first reverse horizontal direction (−X direction) opposite to the first horizontal direction,, a wiring structure positioned above the upper semiconductor die stack, and bonding wire groups connecting the lower semiconductor dies and the upper semiconductor dies to the wiring structure.

The bonding wire groups include a first bonding wire group connecting a first plurality of semiconductor dies selected from the lower semiconductor dies and the upper semiconductor dies to the wiring structure, and a second bonding wire group including bonding wires that each connect a single one of the upper and lower semiconductor dies to the wiring structure.

The first bonding wire group includes a first bonding portion including a first curved wire connecting a second plurality of semiconductor dies of the first plurality of semiconductor dies, a first upward wire connected to the first curved wire and extending toward the wiring structure, a first inclined wire connected to the first upward wire, and a second upward wire extending toward the wiring structure to connect the first inclined wire to the wiring structure. The bonding wires of the second bonding wire group each include a fifth upward wire extending toward the wiring structure to connect a single one of the upper or lower semiconductor dies to the wiring structure.

According to another aspect of the inventive concept, there is provided a semiconductor package including a lower semiconductor die stack in which a plurality of lower semiconductor dies are stacked in a stepwise manner to extend in a first horizontal direction (X direction), an upper semiconductor die stack in which a plurality of upper semiconductor dies are stacked vertically on the lower semiconductor die stack in a stepwise manner to extend in a first reverse horizontal direction (−X direction) opposite to the first horizontal direction, and a wiring structure positioned above the upper semiconductor die stack.

The semiconductor package includes a lower bonding wire group connecting the lower semiconductor dies to the wiring structure, wherein the lower bonding wire group includes a first lower bonding portion including a first lower curved wire connecting at least two of the lower semiconductor dies, a first lower upward wire connected to the first lower curved wire and extending toward the wiring structure, a first lower inclined wire connected to the first lower upward wire, and a second lower upward wire extending toward the wiring structure to connect the first lower inclined wire to the wiring structure.

The semiconductor package includes an upper bonding wire group electrically connecting the upper semiconductor dies to the wiring structure, wherein the upper bonding wire group includes a first upper bonding portion including a first upper curved wire connecting at least two of the upper semiconductor dies, and a first upper upward wire extending toward the wiring structure to connect the first upper curved wire to the wiring structure.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to an embodiment;

FIG. 2 is an enlarged view of the left part of FIG. 1;

FIG. 3 is an enlarged view of the right part of FIG. 1;

FIG. 4 is a plan view illustrating a state in which a first semiconductor die and a second semiconductor die of FIG. 1 are stacked;

FIG. 5 is a cross-sectional view illustrating a semiconductor package according to an embodiment;

FIG. 6 is a cross-sectional view illustrating a semiconductor package according to an embodiment;

FIG. 7 is a cross-sectional view illustrating a semiconductor package according to an embodiment;

FIG. 8 is a cross-sectional view illustrating a semiconductor package according to an embodiment;

FIG. 9 is a cross-sectional view illustrating a semiconductor package according to an embodiment;

FIG. 10 is an enlarged view of the left part of FIG. 9;

FIG. 11 is an enlarged view of the right part of FIG. 9;

FIG. 12 is a cross-sectional view illustrating a semiconductor package according to an embodiment;

FIGS. 13 to 18 are cross-sectional views illustrating a method of manufacturing the semiconductor package of FIG. 1;

FIGS. 19 to 24 are cross-sectional views illustrating a method of manufacturing the semiconductor package of FIG. 9; and

FIGS. 25 to 28 are cross-sectional views illustrating a method of manufacturing a semiconductor package according to an embodiment.

### DETAILED DESCRIPTION OF THE EMBODIMENTS

Hereinafter, embodiments will be described in detail with reference to the accompanying drawings. The invention may, however, be embodied in many different forms and should not be construed as limited to the example embodiments set forth herein. Furthermore, embodiments of the invention may be set forth in an individual drawing, or in a combination of one or more drawings. It should also be emphasized that the disclosure provides details of alternative examples, but such listing of alternatives is not exhaustive. Furthermore, any consistency of detail between various examples should not be interpreted as requiring such detail—it is impracticable to list every possible variation for every feature described herein. The language of the claims should be referenced in determining the requirements of the invention.

In the current specification, components described using singular forms such as “a”, “an”, and “the” are intended to include plural forms of the components as well, unless the context clearly indicates otherwise. In the current specification, the drawings are exaggerated to more clearly explain the inventive concept. In the current specification, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

In the current specification, “connected” may mean that components are physically and/or electrically connected. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

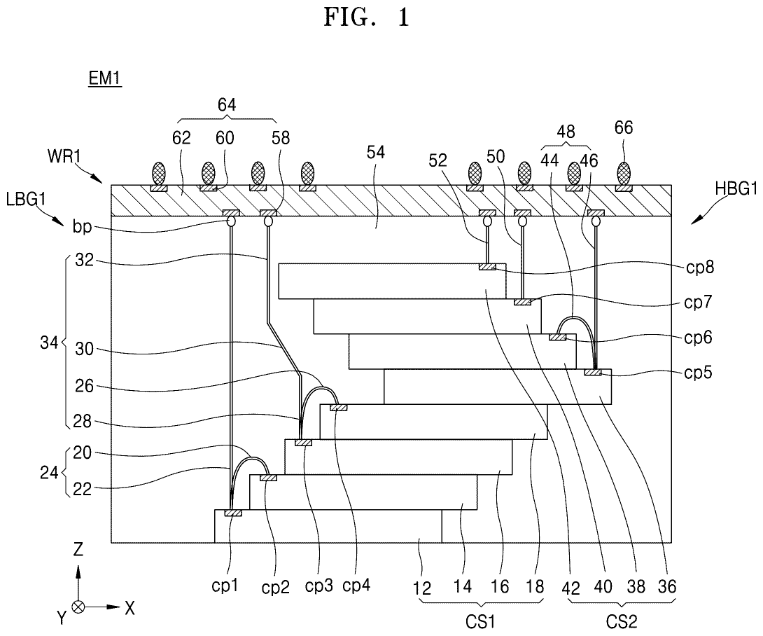

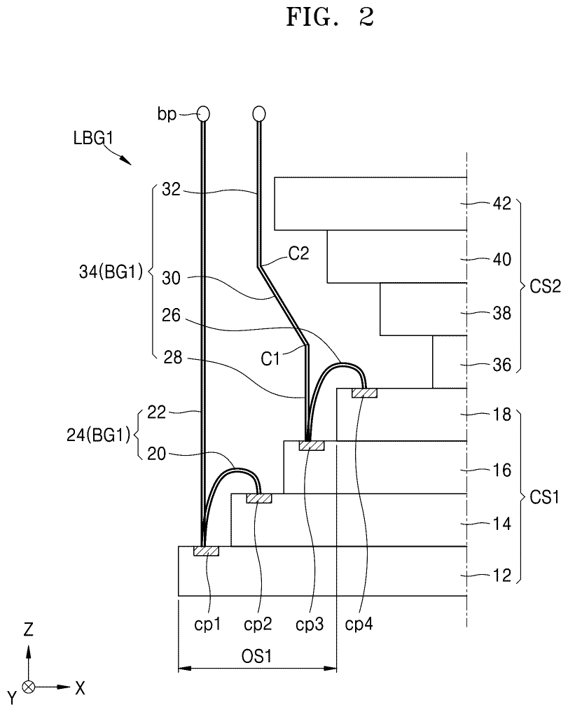

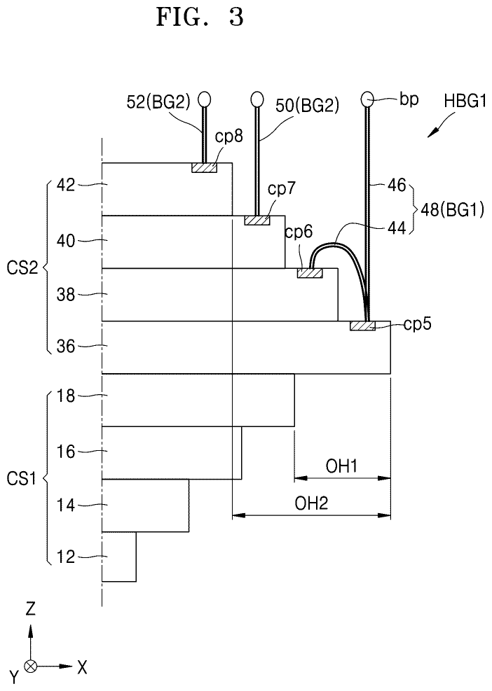

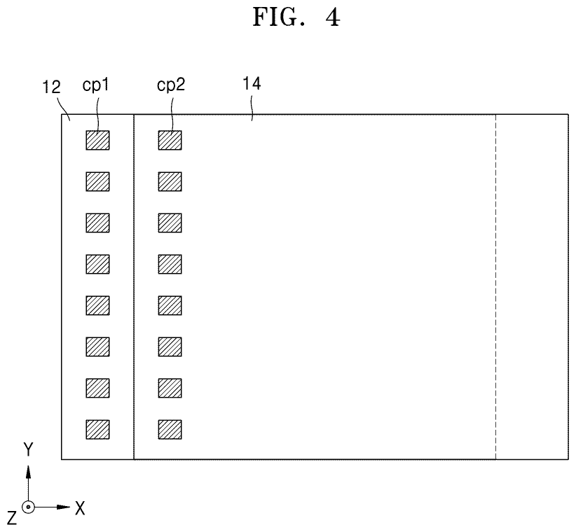

FIG. 1 is a cross-sectional view illustrating a semiconductor package EM1 according to an embodiment, FIG. 2 is an enlarged view of the left part of FIG. 1, FIG. 3 is an enlarged view of the right part of FIG. 1, and FIG. 4 is a plan view illustrating a state in which a first semiconductor die and a second semiconductor die of FIG. 1 are stacked.

Specifically, the semiconductor package EM1 may include a lower semiconductor die stack CS1, an upper semiconductor die stack CS2, a wiring structure WR1, first and second bonding wire groups BG1 and BG2 (refer to FIGS. 2 and 3), and a molding layer 54.

In the lower semiconductor die stack CS1, a plurality of, for example, four lower semiconductor dies (e.g., first to fourth lower semiconductor dies 12, 14, 16, and 18) may be stacked vertically in a stepwise manner to extend in a first horizontal direction (X direction). The first horizontal direction (X direction) may be horizontal relative to top surfaces of the first to fourth lower semiconductor dies 12, 14, 16, and 18 and may be a first stepwise direction in which the first to fourth lower semiconductor dies 12, 14, 16, and 18 are stacked (e.g., the horizontal position of each subsequent die moves in the stepwise direction relative to an immediate underlying die).

An insulating adhesive material such as an adhesive layer, for example, a die attach film (DAF), may be formed among the first to fourth lower semiconductor dies 12, 14, 16, and 18. Each of the first to fourth lower semiconductor dies 12, 14, 16, and 18 may have a thickness of several tens of micrometers μm.

The first to fourth lower semiconductor dies 12, 14, 16, and 18 may respectively include first to fourth lower semiconductor chips. The first to fourth lower semiconductor dies 12, 14, 16, and 18 may include non-volatile memory such as flash memory, phase-change random access memory (PRAM), or magneto-resistive random access memory (MRAM), volatile memory such as dynamic random access memory (DRAM) or static random access memory (SRAM), or non-memory such as a logic circuit.

As illustrated in FIG. 2, the fourth lower semiconductor die 18 may be stacked to be spaced apart from the first lower semiconductor die 12 by a first offset distance OS1 in the first horizontal direction (X direction) (e.g., offset horizontally).

The first lower semiconductor die 12, the second lower semiconductor die 14, the third lower semiconductor die 16, and the fourth lower semiconductor die 18 may each include a first lower die pad cp1, a second lower die pad cp2, a third lower die pad cp3, and a fourth lower die pad cp4, respectively.

As illustrated in FIG. 4, the first lower semiconductor die 12 may include a plurality of first lower die pads cp1 and each of the first lower die pads cp1 may be spaced apart from each other in a second horizontal direction (e.g., the Y direction). The second lower semiconductor die 14 may include a plurality of second lower die pads cp2 and each of the second lower die pads cp2 may be spaced apart from each other in the second horizontal direction. The second horizontal direction (Y direction) may be horizontal relative to the top surfaces of the first to fourth lower semiconductor dies 12, 14, 16, and 18, and perpendicular to the first horizontal direction (X direction) on the top surfaces of the first to fourth lower semiconductor dies 12, 14, 16, and 18.

The first lower die pad cp1 of the first lower semiconductor die 12 and the second lower die pad cp2 of the second lower semiconductor die 14 may have edge pads. For convenience sake, only the first lower semiconductor die 12 and the second lower semiconductor die 14 are illustrated in FIG. 4 with the understanding that the other semiconductor dies may have a similar form.

In the upper semiconductor die stack CS2, a plurality of, for example, four, upper semiconductor dies (e.g., first to fourth upper semiconductor dies 36, 38, 40, and 42) may be stacked vertically in a stepwise manner to extend in a first reverse horizontal direction (−X direction) which may be opposite to the first horizontal direction.

The first reverse horizontal direction (−X direction) may be horizontal relative to top surfaces of the first to fourth upper semiconductor dies 36, 38, 40, and 42 and a second stepwise direction in which the first to fourth upper semiconductor dies 36, 38, 40, and 42 are stacked in contrast to the first stepwise direction of the first to fourth lower semiconductor dies 12, 14, 16, and 18.

An insulating adhesive material such as an adhesive layer, for example, a DAF, may be formed among the first to fourth upper semiconductor dies 36, 38, 40, and 42. Each of the first to fourth upper semiconductor dies 36, 38, 40, and 42 may have a thickness of several tens of micrometers μm.

The first to fourth upper semiconductor dies 36, 38, 40, and 42 may include first to fourth upper semiconductor chips. The first to fourth upper semiconductor dies 36, 38, 40, and 42 may include non-volatile memory such as flash memory, PRAM, or MRAM, volatile memory such as DRAM or SRAM, or non-memory such as a logic circuit.

As illustrated in FIG. 3, the fourth upper semiconductor die 42 may be stacked to be spaced apart from the first upper semiconductor die 36 by a second offset distance OS2 in the first reverse horizontal direction (−X direction) (e.g., offset horizontally). In some embodiments, the second offset distance OS2 may be the same as the first offset distance OS1.

As illustrated in FIG. 3, the first upper semiconductor die 36 may protrude beyond one end of the fourth lower semiconductor die 18 by a first overhang distance OH1. In some embodiments, the first overhang distance OH1 may be less than the second offset distance OS2. The first overhang distance OH1 may be reduced by a first bonding portion 34 as will be described later, and accordingly, the size of the semiconductor package EM1 in the first horizontal direction (X direction) may also be reduced.

The first upper semiconductor die 36, the second upper semiconductor die 38, the third upper semiconductor die 40, and the fourth upper semiconductor die 42 may include a first upper die pad cp5, a second upper die pad cp6, a third upper die pad cp7, and a fourth upper die pad cp8, respectively. Each of the first to fourth upper semiconductor dies 36, 38, 40, and 42 may have an edge pad like those shown in FIG. 4.

The wiring structure WR1 may be positioned above the upper semiconductor die stack CS2. The wiring structure WR1 may include a wiring board 64 and external connection terminals 66. The wiring board 64 may include a substrate body 62, internal wiring pads 58, and external wiring pads 60. In some embodiments, the wiring board 64 may include a printed circuit board (PCB). The internal wiring pads 58 and the external wiring pads 60 may be formed of and/or include a metal such as copper (Cu), aluminum (Al), tungsten (W), titanium (Ti), nickel (Ni), or tin (Sn). The external connection terminals 66 may be connected to the external wiring pads 60, respectively.

The first and second bonding wire groups BG1 and BG2 (refer to FIGS. 2 and 3) may connect the first to fourth lower semiconductor dies 12, 14, 16, and 18 and the first and fourth upper semiconductor dies 36, 38, 40, and 42 to the wiring structure WR1. The first and second bonding wire groups group BG1 and BG2 (refer to FIGS. 2 and 3) may include a lower bonding wire group LBG1 connecting the first to fourth lower semiconductor dies 12, 14, 16, and 18 to the wiring structure WR1, and an upper bonding wire group HBG1 connecting the first to fourth upper semiconductor dies 36, 38, 40, and 42 to the wiring structure WR1.

The first and second bonding wire groups BG1 and BG2 (refer to FIGS. 2 and 3) may include bonding wires. The bonding wires may be formed of and/or include a metal such as gold (Au), silver (Ag), Cu, or platinum (Pt), which may be welded to die pads by ultrasonic energy and/or heat, or an alloy thereof. The bonding wires may have a length of hundreds of micrometers μm.

The first bonding wire group BG1 connects a plurality of upper and lower semiconductor dies selected from the first to fourth lower semiconductor dies 12, 14, 16, and 18 and the first to fourth upper semiconductor dies 36, 38, 40, and 42 to the wiring structure WR1. Each bonding wire of the first bonding wire group BG1 may be connected to at least two of the semiconductor dies selected from the first to fourth lower semiconductor dies 12, 14, 16, and 18 or the first to fourth upper semiconductor dies 36, 38, 40, and 42.

In some embodiments, the first bonding wire group BG1 may connect the first lower semiconductor die 12 and the second lower semiconductor die 14 to the wiring structure WR1. In some embodiments, a bonding wire of the first bonding wire group BG1 may connect the first lower semiconductor die 12 and the second lower semiconductor die 14 to the wiring structure WR1. In some embodiments, the first bonding wire group BG1 may connect the third lower semiconductor die 16 and the fourth lower semiconductor die 18 to the wiring structure WR1. In some embodiments, a bonding wire of the first bonding wire group BG1 may connect the third lower semiconductor die 16 and the fourth lower semiconductor die 18 to the wiring structure WR1.

As illustrated in FIG. 2, the first bonding wire group BG1 may include the first bonding portion 34 including a first curved wire 26 connecting a plurality of upper and lower semiconductor dies, for example, the third and fourth lower semiconductor dies 16 and 18, a first upward wire 28 connected to the first curved wire 26 and extending toward the wiring structure WR1, a first inclined wire 30 connected to the first upward wire 28, and a second upward wire 32 extending toward the wiring structure WR1 to connect the first inclined wire 30 to the wiring structure WR1.

As illustrated in FIG. 2, a first connection point Cl between the first upward wire 28 and the first inclined wire 30 may be configured to overlap vertically with some of the first to fourth upper semiconductor dies 36, 38, 40, and 42, for example, the fourth upper semiconductor die 42 as shown in FIG. 2.

In addition, as illustrated in FIG. 2, a second connection point C2 between the first inclined wire 30 and the second upward wire 32 may be configured not to overlap vertically with the first to fourth upper semiconductor dies 36, 38, 40, and 42.

The first curved wire 26 may connect the third lower die pad cp3 to the fourth lower die pad cp4. An end of the second upward wire 32 may include a spherical ball bp. The spherical ball bp may be referred to as a free air ball.

Because the first bonding portion 34 includes the first curved wire 26, the first upward wire 28, the first inclined wire 30, and the second upward wire 32 to easily connect the plurality of upper and lower semiconductor dies, for example, the third and fourth lower semiconductor dies 16 and 18 to the wiring structure WR1, the first overhang distance OH1 of the semiconductor package EM1 may be effectively reduced.

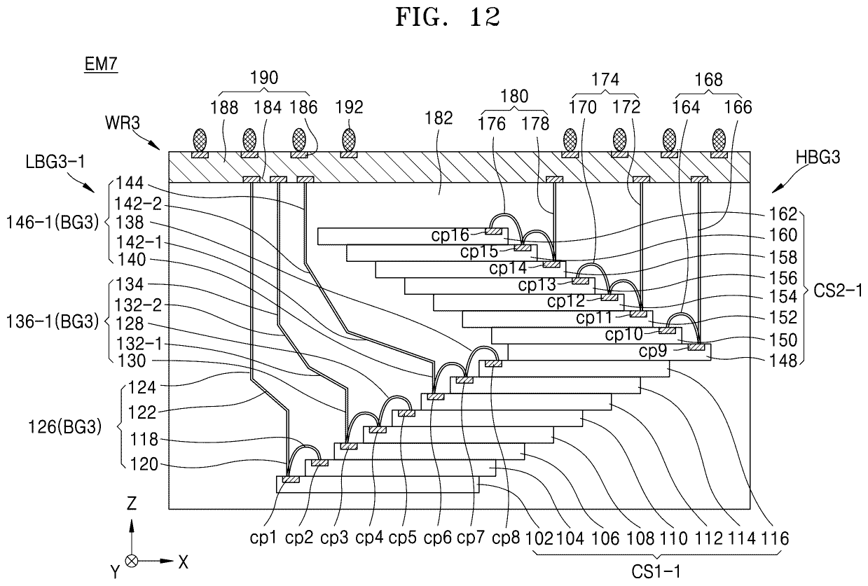

In the semiconductor package EM1 of FIG. 1, the first inclined wire 30 is shown as being inclined at a single angle relative to the first upward wire 28. However, when the first inclined wire 30 is configured to be relatively long, similar to FIG. 12, the first inclined wire 30 may be configured to be inclined at multiple angles relative to the first upward wire, for example, twice, from the first upward wire 28.

As illustrated in FIG. 2, the first bonding wire group BG1 may further include a second bonding portion 24 including a second curved wire 20 connecting a plurality of upper and lower semiconductor dies that are not connected by the first bonding portion 34, for example, the first and second lower semiconductor dies 12 and 14, and a third upward wire 22 extending toward the wiring structure WR1 to connect the second curved wire 20 to the wiring structure WR1. The second curved wire 20 may connect the first lower die pad cp1 to the second lower die pad cp2. An end of the third upward wire 22 may include a spherical ball bp.

In some embodiments, the first bonding wire group BG1 may connect the first upper semiconductor die 36 and the second upper semiconductor die 38 to the wiring structure WR1 as illustrated in FIG. 3.

The first bonding wire group BG1 may further include a third bonding portion 48 including a third curved wire 44 connecting a plurality of upper and lower semiconductor dies, for example, the first and second upper semiconductor dies 36 and 38, and a fourth upward wire 46 extending toward the wiring structure WR1 to connect the third curved wire 44 to the wiring structure WR1 as illustrated in FIG. 3. The third curved wire 44 may connect the first upper die pad cp5 to the second upper die pad cp6. An end of the fourth upward wire 46 may include a spherical ball bp.

Individual bonding wires of the second bonding wire group BG2 connect one semiconductor die (i.e., a single die) selected from the first to fourth lower semiconductor dies 12, 14, 16, and 18 and the first to fourth upper semiconductor dies 36, 38, 40, and 42 to the wiring structure WR1.

In some embodiments, a bonding wire of the second bonding wire group BG2 may include a fifth upward wire 50 connecting one upper or lower semiconductor die, for example, the third upper semiconductor die 40, to the wiring structure WR1 and extending toward the wiring structure WR1. A bonding wire of the second bonding wire group BG2 may include a sixth upward wire 52 connecting one upper or lower semiconductor die, for example, the fourth upper semiconductor die 42, to the wiring structure WR1 and extending toward the wiring structure WR1. Ends of the fifth upward wire 50 and the sixth upward wire 52 may include spherical balls bp.

In FIG. 1, for the sake of convenience, the third and fourth lower semiconductor dies 16 and 18 and the wiring structure WR1 are depicted as being connected to the lower bonding wire group LBG1 only by using the first inclined wire 30, but embodiments are not so limited. In some embodiments, the first and second lower semiconductor dies of the lower bonding wire group LBG1 may also be connected to the wiring structure WR1 by using inclined wires according to positions of the internal wiring pads 58 of the wiring board 64.

In some embodiments, at least one of the first to fourth upper semiconductor dies 36, 38, 40, and 42 of the upper bonding wire group HBG1 may also be connected to the wiring structure WR1 by using an inclined wire according to the positions of the internal wiring pads 58 of the wiring board 64.

The molding layer 54 may mold the lower semiconductor die stack CS1, the upper semiconductor die stack CS2, and the first and second bonding wire groups BG1 and BG2 (refer to FIGS. 2 and 3). The molding layer 54 may be formed of and/or include an epoxy molding compound (EMC). The molding layer 54 may mold the lower semiconductor die stack CS1, the upper semiconductor die stack CS2, the lower bonding wire group LBG1, and the upper bonding wire group HBG1. A top surface of the molding layer 54 may be coplanar with top surfaces of the spherical balls bp of the ends of the second upward wire 32, the third upward wire 22, the fourth upward wire 46, the fifth upward wire 50, and the sixth upward wire 52.

The wiring structure WR1 may be positioned on the molding layer 54. The spherical balls bp of the ends of the second upward wire 32, the third upward wire 22, the fourth upward wire 46, the fifth upward wire 50, and the sixth upward wire 52 may be connected to the internal wiring pads 58 of the wiring board 64. Because the ends of the second upward wire 32, the third upward wire 22, the fourth upward wire 46, the fifth upward wire 50, and the sixth upward wire 52 include the spherical balls bp, the ends of the second upward wire 32, the third upward wire 22, the fourth upward wire 46, the fifth upward wire 50, and the sixth upward wire 52 may be easily connected to the internal wiring pads 58 of the wiring board 64.

For convenience sake, it is illustrated in FIGS. 1 to 4 that the first to fourth upper and lower semiconductor dies 12, 14, 16, 18, 36, 38, 40, and 42 are stacked in the first horizontal direction (X direction) and the first reverse horizontal direction (−X direction). However, in the semiconductor package EM1 according to the inventive concept, the first to fourth upper and lower semiconductor dies 12, 14, 16, 18, 36, 38, 40, and 42 may be stacked in the second horizontal direction (Y direction) and a second reverse horizontal direction opposite to the second horizontal direction (−Y direction).

In the semiconductor package EM1 as described above, the first to fourth upper and lower semiconductor dies 12, 14, 16, 18, 36, 38, 40, and 42 may be easily connected to the wiring structure WR1 by using the first and second bonding wire groups BG1 and BG2.

In addition, because the semiconductor package EM1 includes the first bonding portion 34 including the first curved wire 26, the first upward wire 28, the first inclined wire 30, and the second upward wire 32, the first overhang distance OH1 of the semiconductor package EM1 may be effectively reduced. Accordingly, the size of the semiconductor package EM1 in the first horizontal direction (X direction) may be reduced.

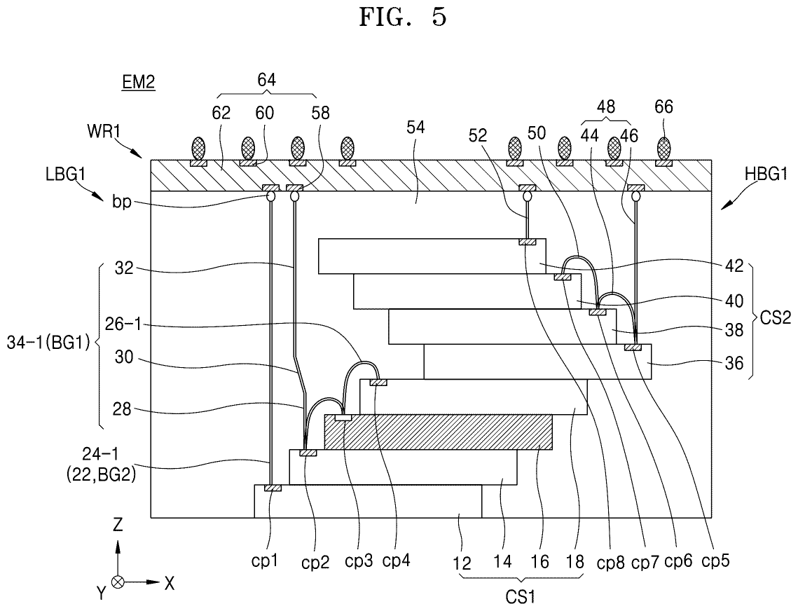

FIG. 5 is a cross-sectional view illustrating a semiconductor package EM2 according to an embodiment.

Specifically, the semiconductor package EM2 may be the same as the semiconductor packages EM1 of FIGS. 1 to 4 except that the configurations of the first bonding wire group BG1 and the second bonding wire group BG2 constituting the lower bonding wire group LBG1 are different. Description previously given with reference to FIGS. 1 to 4 may not be given again with reference to FIG. 5.

As illustrated in FIG. 5, a first bonding wire group BG1 may include a first bonding portion 34-1 including a first curved wire 26-1 connecting a plurality of upper and lower semiconductor dies, for example, second to fourth lower semiconductor dies 14, 16, and 18, a first upward wire 28 extending toward a wiring structure WR1 and connected to the first curved wire 26-1, a first inclined wire 30 connected to the first upward wire 28, and a second upward wire 32 extending toward the wiring structure WR1 to connect the first inclined wire 30 to the wiring structure WR1. The first curved wire 26-1 may connect a second lower die pad cp2, a third lower die pad cp3, and a fourth lower die pad cp4.

The second bonding wire group BG2 may include a second bonding portion 24-1 including one lower semiconductor die that is not connected by the first bonding portion 34-1, for example, a third upward wire 22 connecting to the first lower semiconductor die 12 and extending toward the wiring structure WR1.

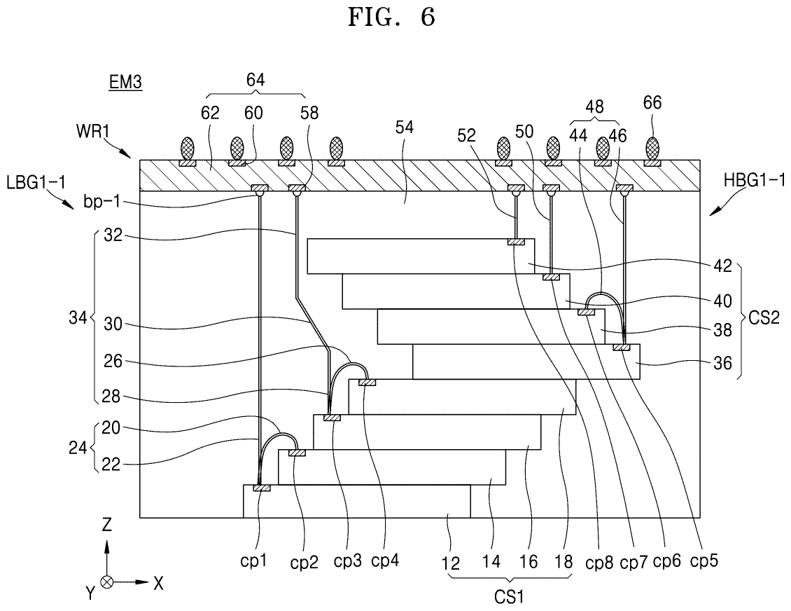

FIG. 6 is a cross-sectional view illustrating a semiconductor package EM3 according to an embodiment.

Specifically, the semiconductor package EM3 may be the same as the semiconductor packages EM1 of FIGS. 1 to 4 except that ends of second to sixth upward wires 32, 22, 46, 50, and 52 of a lower bonding wire group LBG1-1 and an upper bonding wire group HBG1-1 include hemispherical balls bp-1. Description previously given with reference to FIGS. 1 to 4 may not be given again with reference to FIG. 6.

The lower bonding wire group LBG1-1 may include the second upward wire 32 and the third upward wire 22. The ends of the second upward wire 32 and the third upward wire 22 connected to a wiring structure WR1 may include hemispherical balls bp-1.

The upper bonding wire group HBG1-1 may include the fourth upward wire 46, the fifth upward wire 50, and the sixth upward wire 52. The ends of the fourth upward wire 46, the fifth upward wire 50, and the sixth upward wire 52 connected to the wiring structure WR1 may include hemispherical balls bp-1.

When the ends of the second to sixth upward wires 32, 22, 46, 50, and 52 include the hemispherical balls bp-1, the second to sixth upward wires 32, 22, 46, 50, and 52 may be easily connected to internal wiring pads 58 of a wiring board 64.

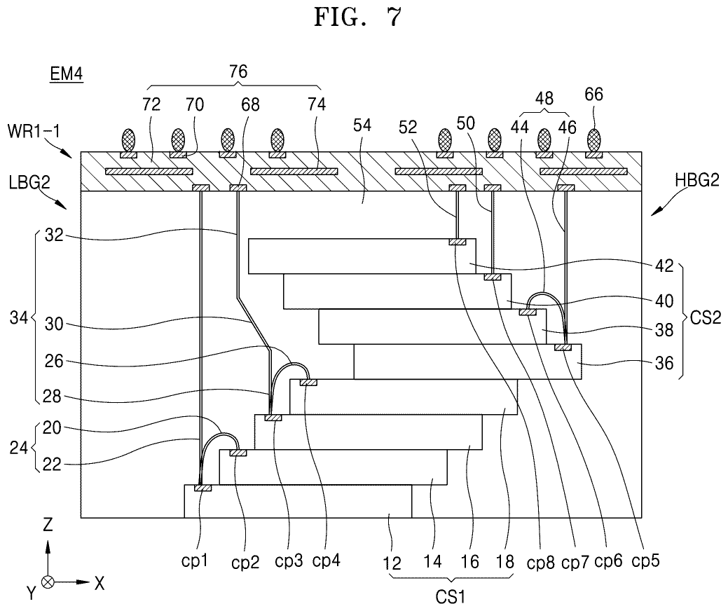

FIG. 7 is a cross-sectional view illustrating a semiconductor package EM4 according to an embodiment.

Specifically, the semiconductor package EM4 may be the same as the semiconductor package EM1 of FIGS. 1 to 4 except that a wiring structure WR-1 includes a redistribution structure 76. Description previously given with reference to FIGS. 1 to 4 may not be given again with reference to FIG. 7.

A lower bonding wire group LBG2 may include a second upward wire 32 and a third upward wire 22. Ends of the second upward wire 32 and the third upward wire 22 connected to a wiring structure WR1-1 may have flat surfaces rather than ball shapes.

An upper bonding wire group HBG2 may include a fourth upward wire 46, a fifth upward wire 50, and a sixth upward wire 52. Ends of the fourth upward wire 46, the fifth upward wire 50, and the sixth upward wire 52 connected to the wiring structure WR1-1 may have flat surfaces rather than ball shapes.

The wiring structure WR1-1 may be arranged on the lower bonding wire group LBG2, the upper bonding wire group HBG2, and a molding layer 54. The wiring structure WR-1 may include a redistribution structure 76. The redistribution structure 76 may include a redistribution body 72, internal redistribution pads 68, a redistribution layer 74, and external redistribution pads 70.

The redistribution layer 74 may be formed of and/or include a metal such as Cu, Al, W, or Ti. The internal redistribution pads 68 and the external redistribution pads 70 may be formed of and/or include a metal such as Cu, Al, W, Ti, Ni, or Sn. The wiring structure WR1-1 may include external connection terminals 66 respectively connected to the external redistribution pads 70.

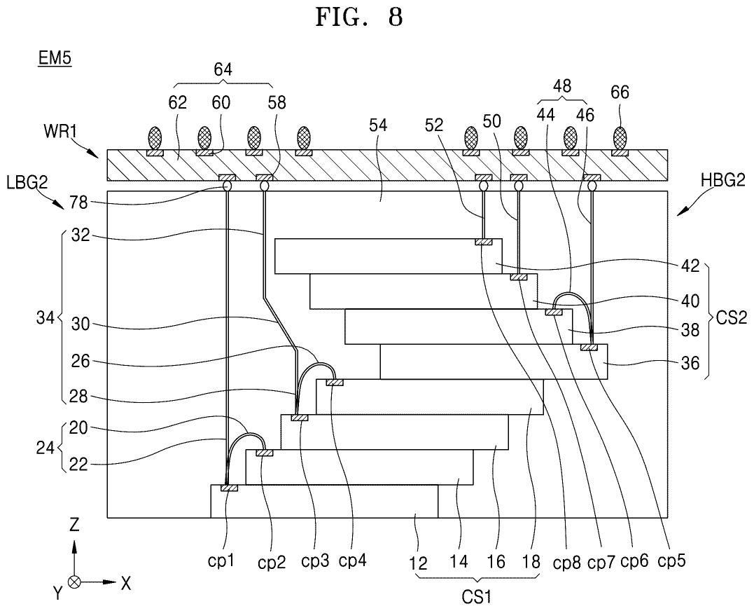

FIG. 8 is a cross-sectional view illustrating a semiconductor package EM5 according to an embodiment.

Specifically, the semiconductor package EM5 may be the same as the semiconductor packages EM1 of FIGS. 1 to 4 except that connection solder balls 78 are further formed on a lower bonding wire group LBG2 and an upper bonding wire group HBG2. Description previously given with reference to FIGS. 1 to 4 may not be given again with reference to FIG. 8.

The lower bonding wire group LBG2 may include a second upward wire 32 and a third upward wire 22. Ends of the second upward wire 32 and the third upward wire 22 connected to a wiring structure WR1 may have flat surfaces rather than ball shapes.

The upper bonding wire group HBG2 may include a fourth upward wire 46, a fifth upward wire 50, and a sixth upward wire 52. Ends of the fourth upward wire 46, the fifth upward wire 50, and the sixth upward wire 52 connected to the wiring structure WR1 may have flat surfaces rather than ball shapes.

The connection solder balls 78 may be formed on the second upward wire 32, the third upward wire 22, the fourth upward wire 46, the fifth upward wire 50, and the sixth upward wire 52. The connection solder balls 78 may be formed of and/or include a low-strength solder composition including Sn as a base metal and Ag and Cu as auxiliary metals. The connection solder balls 78 may be formed of and/or include a high-strength solder composition including Ag as a base metal and Cu and bismuth (Bi) as auxiliary metals.

The wiring structure WR1 may be arranged on the lower bonding wire group LBG2, the upper bonding wire group HBG2, and the connection solder balls 78 on a molding layer 54. Internal wiring pads 58 of the wiring structure WR1 may be easily connected to the second to sixth upward wires 32, 22, 46, 50, and 52.

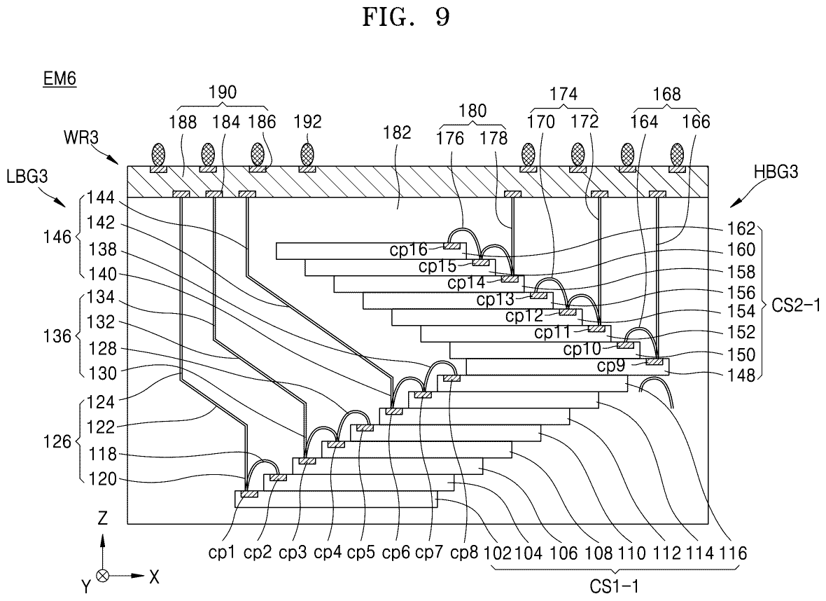

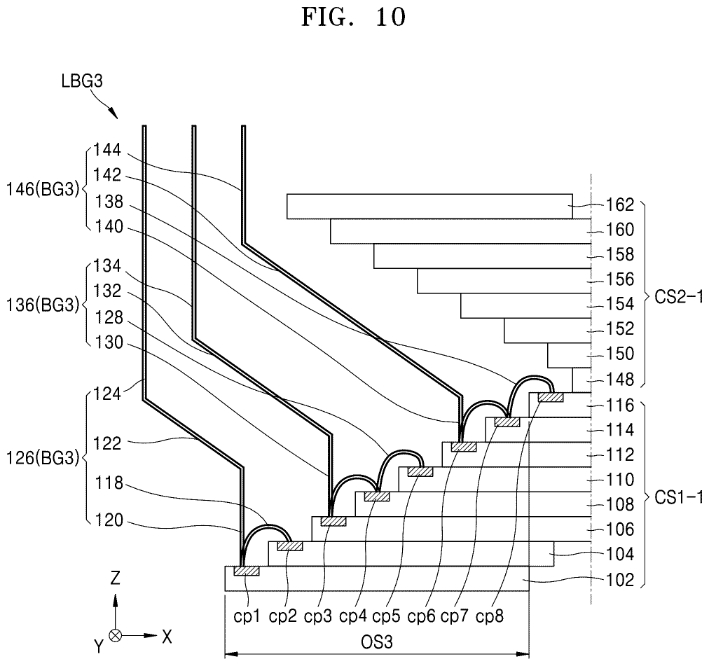

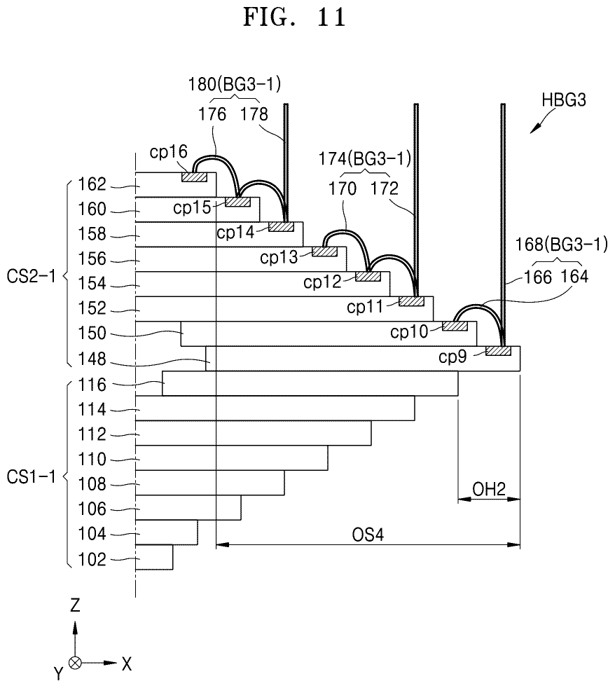

FIG. 9 is a cross-sectional view illustrating a semiconductor package EM6 according to an embodiment, FIG. 10 is an enlarged view of the left part of FIG. 9, and FIG. 11 is an enlarged view of the right part of FIG. 9.

Specifically, the semiconductor package EM6 may include a lower semiconductor die stack CS1-1, an upper semiconductor die stack CS2-1, a wiring structure WR3, and first and second bonding wire groups BG3 and BG3-1 (refer to FIGS. 10 and 11), and a molding layer 182.

In the lower semiconductor die stack CS1-1, a plurality of, for example, eight lower semiconductor dies (e.g., first to eighth lower semiconductor dies 102, 104, 106, 108, 110, 112, 114, and 116) may be stacked vertically in a stepwise manner to extend in the first horizontal direction (X direction). The first horizontal direction (X direction) may be horizontal relative to top surfaces of the first to eighth lower semiconductor dies 102, 104, 106, 108, 110, 112, 114, and 116 and a first stepwise direction in which the first to eighth lower semiconductor dies 102, 104, 106, 108, 110, 112, 114, and 116 are stacked.

An insulating adhesive material such as an adhesive layer, for example, a DAF, may be formed among the first to eighth lower semiconductor dies 102, 104, 106, 108, 110, 112, 114, and 116. Each of the first to eighth lower semiconductor dies 102, 104, 106, 108, 110, 112, 114, and 116 may have a thickness of several tens of micrometers μm.

The first to eighth lower semiconductor dies 102, 104, 106, 108, 110, 112, 114, and 116 may include first to eighth lower semiconductor chips. The first to eighth lower semiconductor dies 102, 104, 106, 108, 110, 112, 114, and 116 may include non-volatile memory such as flash memory, PRAM, or MRAM, volatile memory such as DRAM or SRAM, or non-memory such as a logic circuit.

As illustrated in FIG. 10, the eighth lower semiconductor die 116 may be stacked to be apart from the first lower semiconductor die 102 by a third offset distance OS3 in the first horizontal direction (X direction).

The first lower semiconductor die 102, the second lower semiconductor die 104, the third lower semiconductor die 106, the fourth lower semiconductor die 108, the fifth lower semiconductor die 110, the sixth lower semiconductor die 112, the seventh lower semiconductor die 114, and the eighth lower semiconductor die 116 may include a first lower die pad cp1, a second lower die pad cp2, a third lower die pad cp3, a fourth lower die pad cp4, a fifth lower die pad cp5, a sixth lower die pad cp6, a seventh lower die pad cp7, and an eighth lower die pad cp8, respectively.

Each of the first to eighth lower semiconductor dies 102, 104, 106, 108, 110, 112, 114, and 116 may have an edge pad like in FIG. 4.

In the upper semiconductor die stack CS2-1, a plurality of, for example, eight upper semiconductor dies (e.g., first to eighth upper semiconductor dies 148, 150, 152, 154, 156, 158, 160, and 162) may be stacked vertically in a stepwise manner to extend in the first reverse horizontal direction (−X direction) opposing the first horizontal direction.

The first reverse horizontal direction (−X direction) may be horizontal relative to top surfaces of the first to eighth upper semiconductor dies 148, 150, 152, 154, 156, 158, 160, and 162 and a second stepwise direction in which the first to eighth upper semiconductor dies 148, 150, 152, 154, 156, 158, 160, and 162 are stacked opposite to the first stepwise direction of the first to eighth lower semiconductor dies 102, 104, 106, 108, 110, 112, 114, and 116.

An insulating adhesive material such as an adhesive layer, for example, a DAF, may be formed among the first to eighth upper semiconductor dies 148, 150, 152, 154, 156, 158, 160, and 162. Each of the first to eighth upper semiconductor dies 148, 150, 152, 154, 156, 158, 160, and 162 may have a thickness of several tens of micrometers μm.

The first to eighth upper semiconductor dies 148, 150, 152, 154, 156, 158, 160, and 162 may include first to eighth upper semiconductor chips. The first to eighth upper semiconductor dies 148, 150, 152, 154, 156, 158, 160, and 162 may include non-volatile memory such as flash memory, PRAM, or MRAM, volatile memory such as DRAM or SRAM, or non-memory such as a logic circuit.

As illustrated in FIG. 11, the eighth upper semiconductor die 162 may be stacked to be apart from the first upper semiconductor die 148 by a fourth offset distance OS4 in the first reverse horizontal direction (−X direction). In some embodiments, the fourth offset distance OS4 may be the same as the third offset distance OS3.

As illustrated in FIG. 11, the first upper semiconductor die 148 may protrude beyond one end of the eighth lower semiconductor die 116 by a second overhang distance OH2. In some embodiments, the second overhang distance OH2 may be less than the fourth offset distance OS4. The second overhang distance OH2 may be reduced by the first to third lower bonding portions 126, 136, and 146 as will be described later, and accordingly, the size of the semiconductor package EM6 in the first horizontal direction (X direction) may also be reduced.

The first upper semiconductor die 148, the second upper semiconductor die 150, the third upper semiconductor die 152, the fourth upper semiconductor die 154, the fifth upper semiconductor die 156, the sixth upper semiconductor die 158, the seventh upper semiconductor die 160, and the eighth upper semiconductor die 162 may include a first upper die pad cp9, a second upper die pad cp10, a third upper die pad cp11, a fourth upper die pad cp12, a fifth upper die pad cp13, a sixth upper die pad cp14, a seventh upper die pad cp15, and an eighth upper die pad cp16, respectively.

Each of the first to eighth upper semiconductor dies 148, 150, 152, 154, 156, 158, 160, and 162 may have an edge pad like in FIG. 4.

The wiring structure WR3 may be positioned above the upper semiconductor die stack CS2-1. The wiring structure WR3 may include a wiring board 190 and external connection terminals 192. The wiring board 190 may include a substrate body 188, internal wiring pads 184, and external wiring pads 186. In some embodiments, the wiring board 190 may include a PCB. The external connection terminals 192 may be connected to the external wiring pads 186, respectively.

The first and second bonding wire groups BG3 and BG3-1 (refer to FIGS. 10 and 11) may connect the first to eighth lower semiconductor dies 102, 104, 106, 108, 110, 112, 114, and 116 and the first to eighth upper semiconductor dies 148, 150, 152, 154, 156, 158, 160, and 162 to the wiring structure WR3.

The first and second bonding wire groups BG3 and BG3-1 (refer to FIGS. 10 and 11) may include bonding wires. The bonding wires may be formed of and/or include a metal such as Au, Ag, Cu, or Pt, which may be welded to die pads by ultrasonic energy and/or heat, or an alloy thereof. The bonding wires may have a length of hundreds of micrometers μm.

The first and second bonding wire groups BG3 and BG3-1 (refer to FIGS. 10 and 11) may include a lower bonding wire group LBG3 connecting the first to eighth lower semiconductor dies 102, 104, 106, 108, 110, 112, 114, and 116 to the wiring structure WR3, and an upper bonding wire group HBG3 connecting the first to eighth upper semiconductor dies 148, 150, 152, 154, 156, 158, 160, and 162 to the wiring structure WR3.

The first bonding wire group BG3 connects a plurality of lower semiconductor dies selected from the first to eighth lower semiconductor dies 102, 104, 106, 108, 110, 112, 114, and 116 to the wiring structure WR3.

In some embodiments, the first bonding wire group BG3 may connect the first lower semiconductor die 102 and the second lower semiconductor die 104 to the wiring structure WR3. In some embodiments, the first bonding wire group BG3 may connect the third lower semiconductor die 106, the fourth lower semiconductor die 108, and the fifth lower semiconductor die 110 to the wiring structure WR3. In some embodiments, the first bonding wire group BG3 may connect the sixth lower semiconductor die 112, the seventh lower semiconductor die 114, and the sixth lower semiconductor die 116 to the wiring structure WR3.

As illustrated in FIG. 10, the lower bonding wire group LBG3 may include a first lower bonding portion 126 including a first lower curved wire 118 connecting a plurality of lower semiconductor dies, for example, the first and second lower semiconductor dies 102 and 104 to each other, a first lower upward wire 120 connected to the first lower curved wire 118 and extending toward the wiring structure WR3, a first lower inclined wire 122 connected to the first lower upward wire 120, and a second lower upward wire 124 extending toward the wiring structure WR3 to connect the first lower inclined wire 122 to the wiring structure WR3.

The first lower curved wire 118 may connect the first lower die pad cp1 to the second lower die pad cp2. An end of the second lower upward wire 124 may have a flat surface. In some embodiments, the end of the second lower upward wire 124 may include a spherical ball.

As illustrated in FIG. 10, the lower bonding wire group LBG3 may include a second lower bonding portion 136 including a second lower curved wire 128 connecting a plurality of lower semiconductor dies that are not connected by the first lower bonding portion 126, for example, the third to fifth lower semiconductor dies 106, 118, and 120, a third lower upward wire 130 connected to the second lower curved wire 128 and extending toward the wiring structure WR3, a second lower inclined wire 132 connected to the third lower upward wire 130, and a fourth lower upward wire 134 extending toward the wiring structure WR3 to connect the second lower inclined wire 132 to the wiring structure WR3.

The second lower curved wire 128 may connect a third lower die pad cp3, a fourth lower die pad cp4, and a fifth lower die pad cp5. An end of the fourth lower upward wire 134 may have a flat surface. In some embodiments, the end of the fourth lower upward wire 134 may include a spherical ball.

As illustrated in FIG. 10, the lower bonding wire group LBG3 may include a third lower bonding portion 146 including a third lower curved wire 138 connecting a plurality of lower semiconductor dies that are not connected by the first lower bonding portion 126 and the second lower bonding portion 136, for example, the sixth to eighth lower semiconductor dies 112, 114, and 116, a fifth lower upward wire 140 connected to the third lower curved wire 138 and extending toward the wiring structure WR3, a third lower inclined wire 142 connected to the fifth lower upward wire 140, and a sixth lower upward wire 144 extending toward the wiring structure WR3 to connect the third lower inclined wire 142 to the wiring structure WR3.

The third lower curved wire 138 may connect a sixth lower die pad cp6, a seventh lower die pad cp7, and an eighth lower die pad cp8. An end of the sixth lower upward wire 144 may have a flat surface. In some embodiments, the end of the sixth lower upward wire 144 may include a spherical ball.

Because the first to third lower bonding portions 126, 136, and 146 include the first to third lower curved wires 118, 128, and 138, the first to sixth lower upward wires 120, 124, 130, 134, 140 and 144, and the first to third lower inclined wires 122, 132, and 142 to easily connect a plurality of lower semiconductor dies to the wiring structure WR3, the second overhang distance OH2 of the semiconductor package EM6 may be effectively reduced.

The second bonding wire group BG3-1 connects two upper semiconductor dies selected from the first to fourth upper semiconductor dies 36, 38, 40, and 42 to the wiring structure WR3.

In some embodiments, the second bonding wire group BG3-1 may connect the first upper semiconductor die 148 and the second upper semiconductor die 150 to the wiring structure WR3. In some embodiments, the second bonding wire group BG3-1 may connect the third upper semiconductor die 152, the fourth upper semiconductor die 154, and the fifth upper semiconductor die 156 to the wiring structure WR3. In some embodiments, the second bonding wire group BG3-1 may connect the sixth upper semiconductor die 158, the seventh upper semiconductor die 160, and the eighth upper semiconductor die 162 to the wiring structure WR3.

The upper bonding wire group HBG3 may include a first upper bonding portion 168 including a first upper curved wire 164 connecting a plurality of upper semiconductor dies, for example, the first and second upper semiconductor dies 148 and 150, and a first upper upward wire 166 extending toward the wiring structure WR3 to connect the first upper curved wire 164 to the wiring structure WR3 as illustrated in FIG. 11.

The first upper curved wire 164 may connect the first upper die pad cp9 to the second upper die pad cp10. An end of the first upper upward wire 166 may have a flat surface. In some embodiments, the end of the first upper upward wire 166 may include a spherical ball.

The upper bonding wire group HBG3 may include a second upper bonding portion 174 including a second upper curved wire 170 connecting a plurality of upper semiconductor dies that are not connected by the first upper bonding portion 168, for example, the third to fifth upper semiconductor dies 152, 154, and 156, and a second upper upward wire 172 extending toward the wiring structure WR3 to connect the second upper curved wire 170 to the wiring structure WR3 as illustrated in FIG. 11.

The second upper curved wire 164 may connect a third upper die pad cp11, a fourth upper die pad cp12, and a fifth upper die pad cp13. An end of the second upper upward wire 172 may have a flat surface. In some embodiments, the end of the second upper upward wire 172 may include a spherical ball.

The upper bonding wire group HBG3 may include a third upper bonding portion 180 including a third upper curved wire 176 connecting a plurality of upper semiconductor dies that are not connected by the first upper bonding portion 168 and the second upper bonding portion 174, for example, the sixth to eighth upper semiconductor dies 158, 160, and 162, and a third upper upward wire 178 extending toward the wiring structure WR3 to connect the third upper curved wire 176 to the wiring structure WR3 as illustrated in FIG. 11.

The third upper curved wire 176 may connect the sixth upper die pad cp14, the seventh upper die pad cp15, and the eighth upper die pad cp16. An end of the third upper upward wire 178 may have a flat surface. In some embodiments, the end of the third upper upward wire 178 may include a spherical ball.

Because the first to third upper bonding portions 168, 174, and 180 include the first to third upper curved wires 164, 170, and 172 and the first to third upper upward wires 166, 172, and 178 to easily connect a plurality of upper semiconductor dies to the wiring structure WR3, the second overhang distance OH2 of the semiconductor package EM6 may be effectively reduced.

In FIG. 9, for convenience sake, only in the lower bonding wire group LBG3, the first to eighth lower semiconductor dies 102, 104, 106, 108, 110, 112, 114, and 116 are depicted as being connected to the wiring structure WR3 by using the first to third inclined wires 122, 132, and 142, but embodiments are not so limited. In some embodiments, at least one of the first to eighth upper semiconductor dies 148, 150, 152, 154, 156, 158, 160, and 162 of the upper bonding wire group HBG3 may also be connected to the wiring structure WR3 by using an inclined wire according to positions of the internal wiring pads 184 of the wiring board 190.

The molding layer 182 may mold the lower semiconductor die stack CS1-1, the upper semiconductor die stack CS2-1, and the first and second bonding wire groups BG3 and BG3-1 (refer to FIGS. 10 and 11). The molding layer 182 may include an EMC. The molding layer 182 may mold the lower semiconductor die stack CS1-1, the upper semiconductor die stack CS2-1, the lower bonding wire group LBG3, and the upper bonding wire group HBG3. A top surface of the molding layer 182 may be coplanar with top surfaces of the ends of the second lower upward wire 124, the fourth lower upward wire 134, the sixth lower upward wire 144, the first upper upward wire 166, the second upper upward wire 172, and the third upper upward wire 178.

The wiring structure WR3 may be positioned on the molding layer 182. The ends of the second lower upward wire 124, the fourth lower upward wire 134, the sixth lower upward wire 144, the first upper upward wire 166, the second upper upward wire 172, and the third upper upward wire 178 may be connected to the internal wiring pads 184 of the wiring board 190.

For convenience sake, it is illustrated in FIG. 9 that the first to eighth upper and lower semiconductor dies 102, 104, 106, 108, 110, 112, 114, 116, 148, 150, 152, 154, 156, 158, 160, and 162 are stacked in the first horizontal direction (X direction) and the first reverse horizontal direction (−X direction). However, in the semiconductor package EM6 according to the inventive concept, the first to eighth upper and lower semiconductor dies 102, 104, 106, 108, 110, 112, 114, 116, 148, 150, 152, 154, 156, 158, 160, and 162 may be stacked in the second horizontal direction (Y direction) and the second reverse horizontal direction (−Y direction).

In the semiconductor package EM6, the first to eighth upper and lower semiconductor dies 102, 104, 106, 108, 110, 112, 114, 116, 148, 150, 152, 154, 156, 158, 160, and 162 may be easily connected to the wiring structure WR3 by using the first and second bonding wire groups BG3 and BG3-1. In addition, because the semiconductor package EM6 includes the first to third lower bonding portions 126, 136, and 146, the second overhang distance OH2 of the semiconductor package EM6 may be effectively reduced. Accordingly, the size of the semiconductor package EM6 in the first horizontal direction (X direction) may be reduced.

FIG. 12 is a cross-sectional view illustrating a semiconductor package EM7 according to an embodiment.

Specifically, the semiconductor package EM7 may be the same as the semiconductor packages EM6 of FIGS. 9 to 11 except that the configuration of the first bonding wire group BG3 constituting the lower bonding wire group LBG3-1 is different. Description previously given with reference to FIGS. 9 to 11 may not be given again with reference to FIG. 12.

The first bonding wire group BG3 constituting the lower bonding wire group LBG3-1 may include the first lower bonding portion 126. The first lower bonding portion 126 may include a first lower curved wire 118, a first lower upward wire 120 extending toward the wiring structure WR3 and connected to the first lower curved wire 118, a first lower inclined wire 122 connected to the first lower upward wire 120, and a second lower upward wire 124 extending toward the wiring structure WR3 to connect the first lower inclined wire 122 to the wiring structure WR3.

The first bonding wire group BG3 constituting the lower bonding wire group LBG3-1 may include a second lower bonding portion 136-1. The second lower bonding portion 136-1 may include a second lower curved wire 128 connecting a plurality of lower semiconductor dies that are not connected by the first lower bonding portion 126, for example, the third to fifth lower semiconductor dies 106, 108, and 110, a third lower upward wire 130 connected to the second lower curved wire 128 and extending toward the wiring structure WR3, second lower inclined wires 132-1 and 132-2 connected to the third lower upward wire 130, and a fourth lower upward wire 134 extending toward the wiring structure WR3 to connect the second lower inclined wires 132-1 and 132-2 to the wiring structure WR3.

The second lower inclined wires 132-1 and 132-2 may include a first sub-lower inclined wire 132-1 connected to the first lower upward wire 130, and a second sub-lower inclined wire 132-2 connecting the first sub-lower inclined wire 132-1 to the fourth lower upward wire 134. In the current embodiment, the second lower inclined wires 132-1 and 132-2 include two sub-lower inclined wires but may include more sub-lower inclined wires.

The first bonding wire group BG3 constituting the lower bonding wire group LBG3-1 may include a third lower bonding portion 146-1. The third lower bonding portion 146-1 includes a third lower curved wire 138 connecting a plurality of lower semiconductor dies that are not connected by the first lower bonding portion 126 and the second lower bonding portion 136-1, for example, the sixth to eighth lower semiconductor dies 112, 114, and 116, a fifth lower upward wire 140 connected to the third lower curved wire 138 and extending toward the wiring structure WR3, third lower inclined wires 142-1 and 142-2 connected to the fifth lower upward wire 140, and a sixth lower upward wire 144 extending toward the wiring structure WR3 to connect the third lower inclined wires 142-1 and 142-2 to the wiring structure WR3.

The third lower inclined wires 142-1 and 142-2 may include a third sub-lower inclined wire 142-1 connected to the third lower upward wire 140, and a third sub-lower inclined wire 142-2 connecting the third sub-lower inclined wire 142-1 to the sixth lower upward wire 144. In the current embodiment, the third lower inclined wires 142-1 and 142-2 include two sub-lower inclined wires but may include more sub-lower inclined wires.

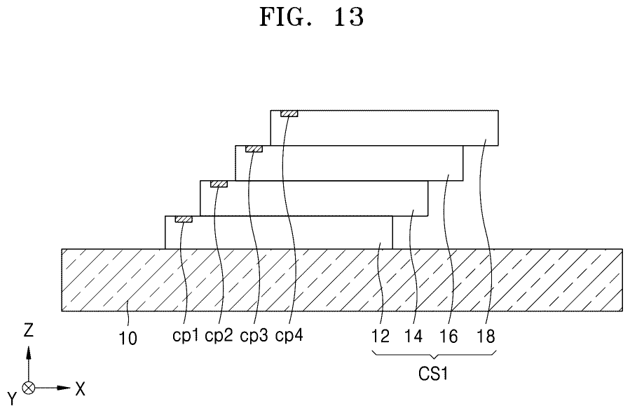

FIGS. 13 to 18 are cross-sectional views illustrating a method of manufacturing the semiconductor package EM1 of FIG. 1.

Specifically, the description previously given with reference to FIG. 1 may be simply given or may not be repeated with reference to FIGS. 13 to 18. Referring to FIG. 13, a lower semiconductor die stack CS1 is formed on a carrier substrate 10. The carrier substrate 10 may include a glass carrier substrate, a silicon carrier substrate, or a ceramic carrier substrate. Alternatively, the carrier substrate 10 may include a wafer.

A plurality of, for example, four lower semiconductor dies (e.g., first to fourth lower semiconductor dies 12, 14, 16, and 18) are stacked vertically on the carrier substrate 10 in a stepwise manner to extend in the first horizontal direction (X direction) to form the lower semiconductor die stack CS1. The first horizontal direction (X direction) may be horizontal relative to top surfaces of the first to fourth lower semiconductor dies 12, 14, 16, and 18 and a first stepwise direction in which the first to fourth lower semiconductor dies 12, 14, 16, and 18 are stacked.

The first to fourth lower semiconductor dies 12, 14, 16, and 18 may include a first lower die pad cp1, a second lower die pad cp2, a third lower die pad cp3, and a fourth lower die pad cp4, respectively.

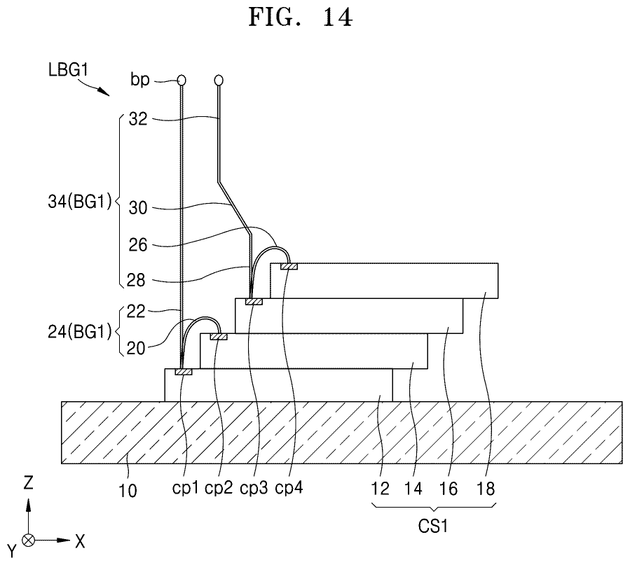

Referring to FIG. 14, a lower bonding wire group LBG1 connected to the lower semiconductor die stack CS1 is formed. The lower bonding wire group LBG1 may include a first bonding wire group BG1 connecting two lower semiconductor dies selected from the first to fourth lower semiconductor dies 12, 14, 16, and 18.

The first bonding wire group BG1 may include a first bonding portion 34 including a first curved wire 26 connecting lower semiconductor dies, for example, the third and fourth lower semiconductor dies 16 and 18, a first upward wire 28 connected to the first curved wire 26 and extending from a top surface of the third lower semiconductor die 16 in an upward direction (Z direction), a first inclined wire 30 connected to the first upward wire 28, and a second upward wire 32 extending from the top surface of the third lower semiconductor die 16 in the upward direction (Z direction) and connected to the first inclined wire 30.

The first curved wire 26 connects the third lower die pad cp3 to the fourth lower die pad cp4. An end of the second upward wire 32 may include a spherical ball bp. The spherical ball bp may be referred to as a free air ball.

The first bonding wire group BG1 may include a second bonding portion 24 including a second curved wire 20 connecting a plurality of lower semiconductor dies that are not connected by the first bonding portion 34, for example, the first and second lower semiconductor dies 12 and 14, and a third upward wire 22 extending from a top surface of the first lower semiconductor die 12 in the upward direction (Z direction) and connected to the second curved wire 20. The second curved wire 20 may connect the first lower die pad cp1 to the second lower die pad cp2. An end of the third upward wire 22 may include a spherical ball bp.

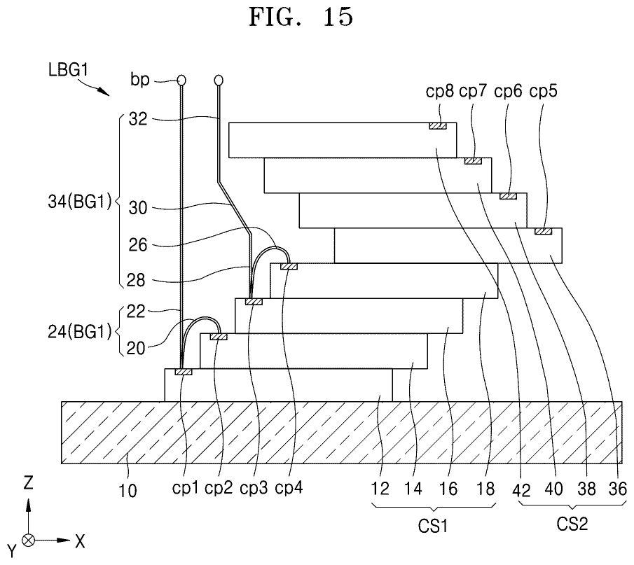

Referring to FIG. 15, an upper semiconductor die stack CS2 is stacked on the lower semiconductor die stack CS1. A plurality of, for example, four upper semiconductor dies (e.g., first to fourth upper semiconductor dies 36, 38, 40, and 42) are stacked vertically on the fourth lower semiconductor die 18 in a stepwise manner to extend in the first reverse horizontal direction (−X direction) opposite to the first horizontal direction (X direction) to form the upper semiconductor die stack CS2.

The first reverse horizontal direction (−X direction) may be horizontal to top surfaces of the first to fourth upper semiconductor dies 36, 38, 40, and 42 and a second stepwise direction in which the first to fourth upper semiconductor dies 36, 38, 40, and 42 are stacked in contrast to the first stepwise direction of the first to fourth lower semiconductor dies 12, 14, 16, and 18.

The first upper semiconductor die 36, the second upper semiconductor die 38, the third upper semiconductor die 40, and the fourth upper semiconductor die 42 may include a first upper die pad cp5, a second upper die pad cp6, a third upper die pad cp7, and a fourth upper die pad cp8, respectively.

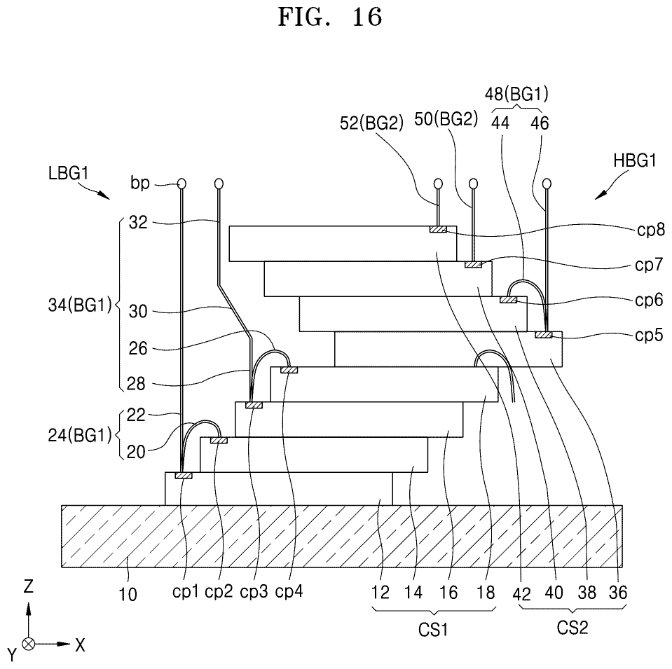

Referring to FIG. 16, an upper bonding wire group HBG1 connected to the upper semiconductor die stack CS2 is formed. The upper bonding wire group HBG1 may include the first bonding wire group BG1 connecting two upper semiconductor dies selected from the first to fourth upper semiconductor dies 36, 38, 40, and 42.

The first bonding wire group BG1 constituting the upper bonding wire group HBG1 may include a third bonding portion 48 including a third curved wire 44 connecting a plurality of upper semiconductor dies, for example, the first and second upper semiconductor dies 36 and 38, and a fourth upward wire 46 extending from a surface of the first upper semiconductor die 36 in the upward direction (Z direction) and connected to the third curved wire 44. The third curved wire 44 may connect the first upper die pad cp5 to the second upper die pad cp6. An end of the fourth upward wire 46 may include a spherical ball bp.

The upper bonding wire group HBG1 may include a second bonding wire group BG2 connecting one upper semiconductor die selected from the first to fourth upper semiconductor dies 36, 38, 40, and 42. The second bonding wire group BG2 may include a fifth upward wire 50 extending from a surface of one upper or lower semiconductor die, for example, the third upper semiconductor die 40, in the upward direction (Z direction).

In addition, the second bonding wire group BG2 may include a sixth upward wire 52 extending from a top surface of one upper semiconductor die, for example, the fourth upper semiconductor die 42, in the upward direction (Z direction). Ends of the fifth upward wire 50 and the sixth upward wire 52 may include spherical balls bp.

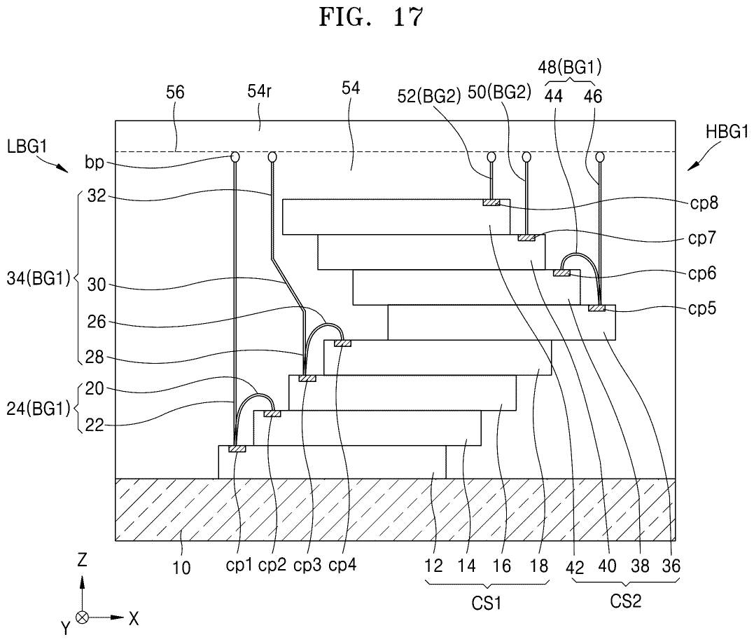

Referring to FIG. 17, a molding material layer 54r molding the lower semiconductor die stack CS1, the upper semiconductor die stack CS2, the lower bonding wire group LBG1, and the upper bonding wire group HBG1 is formed on the carrier substrate 10.

Subsequently, as indicated by reference numeral 56, a molding layer 54 is formed by polishing the molding material layer 54r by using surfaces of spherical balls bp of the second upward wire 32, the third upward wire 22, the fourth upward wire 46, the fifth upward wire 50, and the sixth upward wire 52 as an etching stop point.

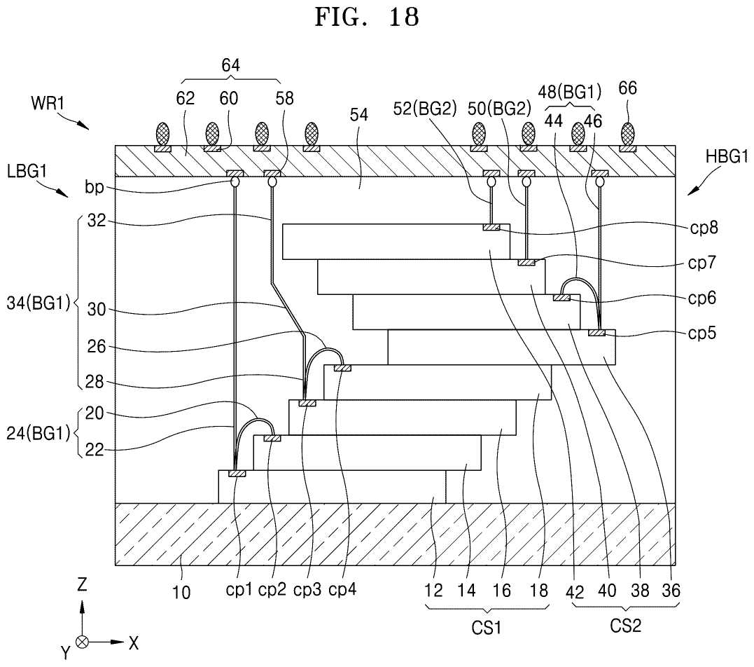

Referring to FIG. 18, a wiring structure WR1 is formed on the molding layer 54. The spherical balls bp of the ends of the second upward wire 32, the third upward wire 22, the fourth upward wire 46, the fifth upward wire 50, and the sixth upward wire 52 are attached to internal wiring pads 58 of a wiring board 64 using a process such as a thermo-compression method. The spherical balls bp of the ends of the second upward wire 32, the third upward wire 22, the fourth upward wire 46, the fifth upward wire 50, and the sixth upward wire 52 are attached to the internal wiring pads 58 of the wiring board 64 by a process such as a thermo-compression method. External connection terminals 66 are formed on external wiring pads 60 of the wiring board 64.

Subsequently, the carrier substrate 10 may be removed to complete the semiconductor package EM1 illustrated in FIGS. 1 to 4. In some embodiments, the carrier substrate 10 may be removed immediately after forming the molding layer 54. The carrier substrate 10 may be removed by irradiating ultraviolet rays onto the carrier substrate 10.

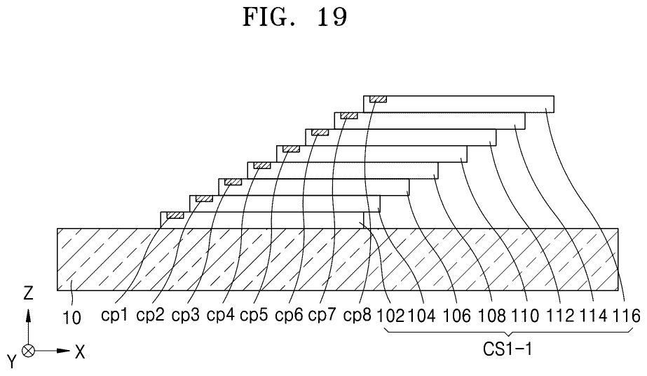

FIGS. 19 to 24 are cross-sectional views illustrating a method of manufacturing the semiconductor package of FIG. 9.

Specifically, description of items previously given with reference to FIG. 9 may be simply given or omitted with reference to FIGS. 19 to 24. Referring to FIG. 19, a lower semiconductor die stack CS1-1 is formed on a carrier substrate 10. A plurality of, for example, eighth lower semiconductor dies 102, 104, 106, 108, 110, 112, 114, and 116 are stacked vertically on the carrier substrate 10 in a stepwise manner to extend in the first horizontal direction (X direction) to form the lower semiconductor die stack CS1-1.

The first horizontal direction (X direction) may be horizontal to top surfaces of the first to eighth lower semiconductor dies 102, 104, 106, 108, 110, 112, 114, and 116 and a first stepwise direction in which the first to eighth lower semiconductor dies 102, 104, 106, 108, 110, 112, 114, and 116 are stacked.

The first lower semiconductor die 102, the second lower semiconductor die 104, the third lower semiconductor die 106, the fourth lower semiconductor die 108, the fifth lower semiconductor die 110, the sixth lower semiconductor die 112, the seventh lower semiconductor die 114, and the eighth lower semiconductor die 116 may include a first lower die pad cp1, a second lower die pad cp2, a third lower die pad cp3, a fourth lower die pad cp4, a fifth lower die pad cp5, a sixth lower die pad cp6, a seventh lower die pad cp7, and an eighth lower die pad cp8, respectively.

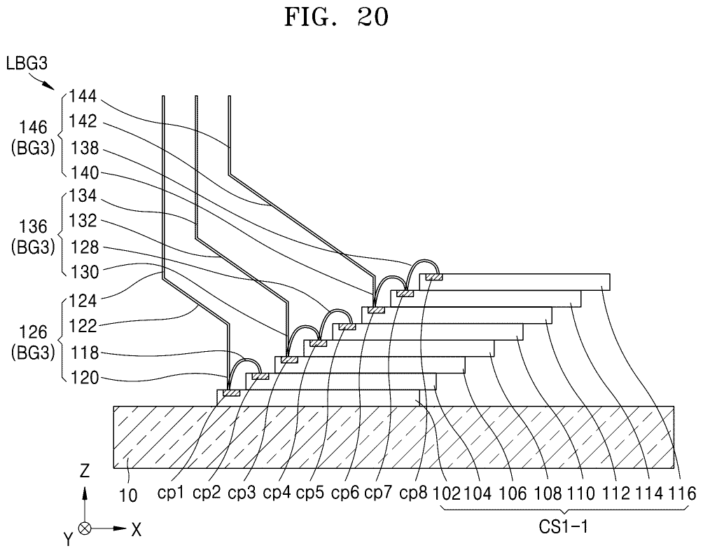

Referring to FIG. 20, a lower bonding wire group LBG3 connected to the lower semiconductor die stack CS1-1 is formed. The lower bonding wire group LBG3 may include a first bonding wire group BG3 connected to a plurality of lower semiconductor dies selected from the first to eighth lower semiconductor dies 102, 104, 106, 108, 110, 112, 114, and 116.

The lower bonding wire group LBG3 may include a first lower bonding portion 126. The first lower bonding portion 126 may include a first lower curved wire 118 connecting the first and second lower semiconductor dies 102 and 104, a first lower upward wire 120 connected to the first lower curved wire 118 and extending from a surface of the first lower semiconductor die 102 in the upward direction (Z direction), a first lower inclined wire 122 connected to the first lower upward wire 120, and a second lower upward wire 124 connected to the first lower inclined wire 122 and extending from the surface of the first lower semiconductor die 102 in the upward direction (Z direction).

The first lower curved wire 118 may connect the first lower die pad cp1 to the second lower die pad cp2. An end of the second lower upward wire 124 may have a flat surface. In some embodiments, the end of the second lower upward wire 124 may include a spherical ball.

The lower bonding wire group LBG3 may include a second lower bonding portion 136. The second lower bonding portion 136 may include a second lower curved wire 128 connecting the third to fifth lower semiconductor dies 106, 118, and 120 that are not connected by the first lower bonding portion 126, a third lower upward wire 130 connected to the second lower curved wire 128 and extending from a surface of the third lower semiconductor die 106 in the upward direction (Z direction), a second lower inclined wire 132 connected to the third lower upward wire 130, and a fourth lower upward wire 134 extending from the surface of the third lower semiconductor die 106 in the upward direction (Z direction) and connected to the second lower inclined wire 132.

The second lower curved wire 128 may connect a third lower die pad cp3, a fourth lower die pad cp4, and a fifth lower die pad cp5. An end of the fourth lower upward wire 134 may have a flat surface. In some embodiments, the end of the fourth lower upward wire 134 may include a spherical ball.

The lower bonding wire group LBG3 may include a third lower bonding portion 146. The third lower bonding portion 146 may include a third lower curved wire 138 connecting the sixth to eighth lower semiconductor dies 112, 114, and 116 that are not connected by the first lower bonding portion 126 and the second lower bonding portion 136, a fifth lower upward wire 140 connected to the third lower curved wire 138 and extending from a surface of the sixth lower semiconductor die 112 in the upward direction (Z direction), a third lower inclined wire 142 connected to the fifth lower upward wire 140, and a sixth lower upward wire 144 connected to the third lower inclined wire 142 and extending from the surface of the sixth lower semiconductor die 112 in the upward direction (Z direction).

The third lower curved wire 138 may connect a sixth lower die pad cp6, a seventh lower die pad cp7, and an eighth lower die pad cp8. An end of the sixth lower upward wire 144 may have a flat surface. In some embodiments, the end of the sixth lower upward wire 144 may include a spherical ball.

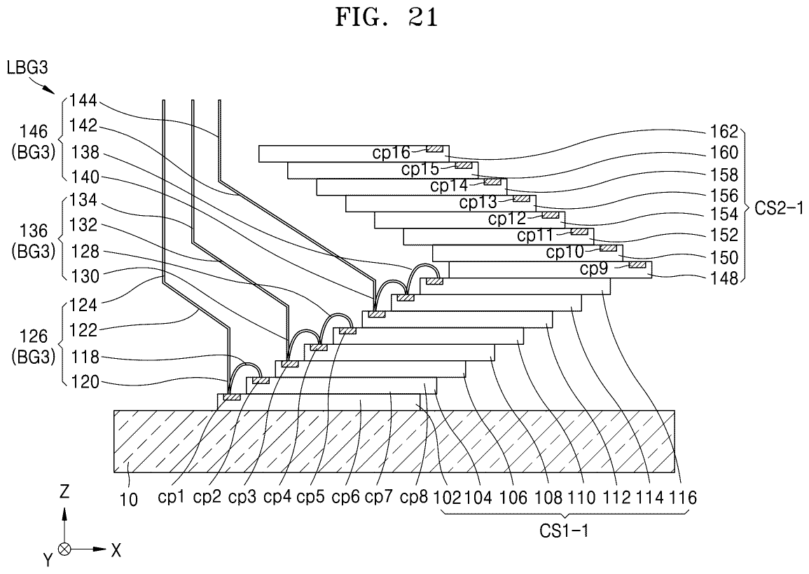

Referring to FIG. 21, an upper semiconductor die stack CS2-1 is stacked on the lower semiconductor die stack CS1-1. The upper semiconductor die stack CS2-1 is formed by vertically stacking the plurality of, for example, the eight upper semiconductor dies 148, 150, 152, 154, 156, 158, 160, and 162 in a stepwise manner to extend in the first reverse horizontal direction (−X direction) opposite to the first horizontal direction.

The first reverse horizontal direction (−X direction) may be horizontal to top surfaces of the first to eighth upper semiconductor dies 148, 150, 152, 154, 156, 158, 160, and 162 and a second stepwise direction in which the first to eighth upper semiconductor dies 148, 150, 152, 154, 156, 158, 160, and 162 are stacked opposite to the first stepwise direction of the first to eighth lower semiconductor dies 102, 104, 106, 108, 110, 112, 114, and 116.

The first upper semiconductor die 148, the second upper semiconductor die 150, the third upper semiconductor die 152, the fourth upper semiconductor die 154, the fifth upper semiconductor die 156, the sixth upper semiconductor die 158, the seventh upper semiconductor die 160, and the eighth upper semiconductor die 162 may include a first upper die pad cp9, a second upper die pad cp10, a third upper die pad cp11, a fourth upper die pad cp12, a fifth upper die pad cp13, a sixth upper die pad cp14, a seventh upper die pad cp15, and an eighth upper die pad cp16, respectively.

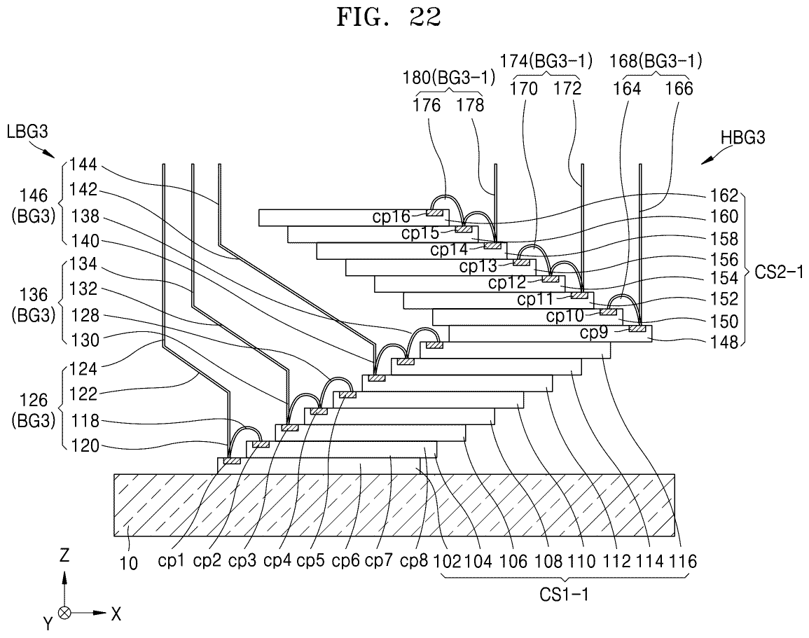

Referring to FIG. 22, an upper bonding wire group HBG3 connected to the upper semiconductor die stack CS2-1 is formed. The upper bonding wire group HBG3 may include a second bonding wire group BG3-1 connected to a plurality of upper semiconductor dies selected from the first to eighth upper semiconductor dies 148, 150, 152, 154, 156, 158, 160, and 162.

The upper bonding wire group HBG3 may include a first upper bonding portion 168. The first upper bonding portion 168 may include a first upper curved wire 164 connecting the first and second upper semiconductor dies 148 and 150, and a first upper upward wire 166 connected to the first upper curved wire 164 and extending from a surface of the first upper semiconductor die 148 in the upward direction (Z direction).

The first upper curved wire 164 may connect the first upper die pad cp9 to the second upper die pad cp10. An end of the first upper upward wire 166 may have a flat surface. In some embodiments, the end of the first upper upward wire 166 may include a spherical ball.

The upper bonding wire group HBG3 may include a second upper bonding portion 174 that is not connected by the first upper bonding portion 168. The second upper bonding portion 174 may include a second upper curved wire 170 connecting the third to fifth upper semiconductor dies 152, 154, and 156, and a second upper upward wire 172 connected to the second upper curved wire 170 and extending from a surface of the third upper semiconductor die 152 in the upward direction (Z direction).

The second upper curved wire 164 may connect a third upper die pad cp11, a fourth upper die pad cp12, and a fifth upper die pad cp13. An end of the second upper upward wire 172 may have a flat surface. In some embodiments, the end of the second upper upward wire 172 may include a spherical ball.

The upper bonding wire group HBG3 may include a third upper bonding portion 180 that is not connected by the first upper bonding portion 168 and the second upper bonding portion 174. The third upper bonding portion 180 may include a third upper curved wire 176 connecting the sixth to eighth upper semiconductor dies 158, 160, and 162, and a third upper upward wire 178 connected to the third upper curved wire 176 and extending from a surface of the sixth upper semiconductor die 158 in the upward direction (Z direction).

The third upper curved wire 176 may connect the sixth upper die pad cp14, the seventh upper die pad cp15, and the eighth upper die pad cp16. An end of the third upper upward wire 178 may have a flat surface. In some embodiments, the end of the third upper upward wire 178 may include a spherical ball.

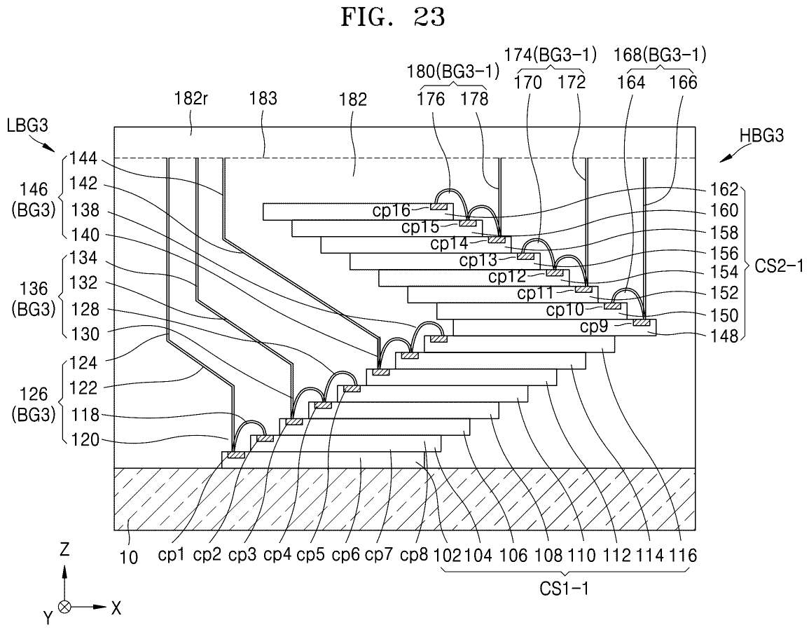

Referring to FIG. 23, a molding material layer 182r molding the lower semiconductor die stack CS1-1, the upper semiconductor die stack CS2-1, the lower bonding wire group LBG3, and the upper bonding wire group HBG3 is formed on the carrier substrate 10.

Subsequently, as indicated by reference numeral 183, a molding layer 182 is formed by polishing the molding material layer 182r by using surfaces of the second lower upward wire 124, the fourth lower upward wire 134, the sixth lower upward wire 144, the first upper upward wire 166, the second upper upward wire 172, and the third upper upward wire 178 as an etching stop point.

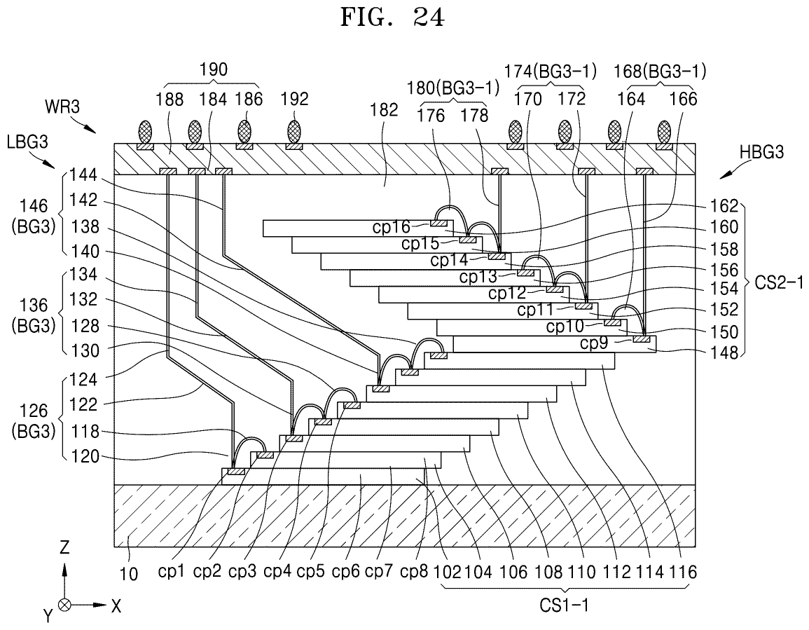

Referring to FIG. 24, a wiring structure WR3 is formed on the molding layer 182. The surfaces of the second lower upward wire 124, the fourth lower upward wire 134, the sixth lower upward wire 144, the first upper upward wire 166, the second upper upward wire 172, and the third upper upward wire 178 are attached to internal wiring pads 184 of a wiring board 190 by a thermo-compression method. External connection terminals 192 are formed on external wiring pads 186 of the wiring board 190.

Subsequently, the carrier substrate 10 may be removed to complete the semiconductor package EM6 illustrated in FIGS. 9 to 11. In some embodiments, the carrier substrate 10 may be removed immediately after forming the molding layer 182. The carrier substrate 10 may be removed by irradiating ultraviolet rays onto the carrier substrate 10.

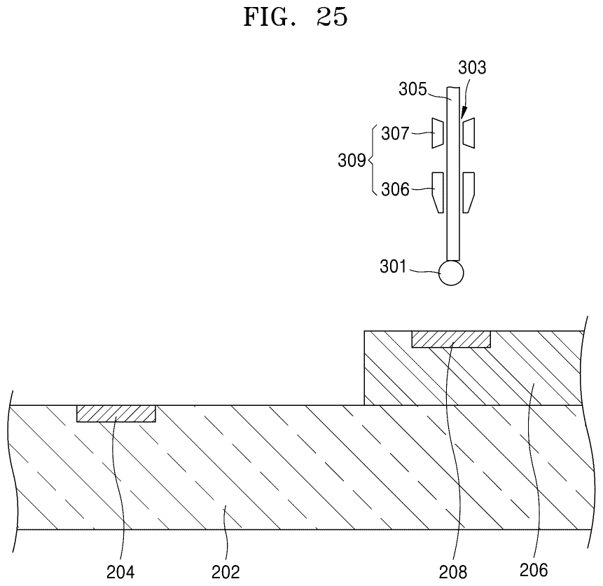

FIGS. 25 to 28 are cross-sectional views illustrating a method of manufacturing a semiconductor package, according to an embodiment.

Specifically, FIGS. 25 to 28 are provided to explain a process of connecting two semiconductor dies 202 and 206 with a bonding wire by using a bonding device. The first and second semiconductor dies 202 and 206 may include the lower semiconductor dies or the upper semiconductor dies described above.

Referring to FIG. 25, the second semiconductor die 206 is mounted stepwise on the first semiconductor die 202. A first die pad 204 may be formed on the first semiconductor die 202. A second die pad 208 may be formed on the second semiconductor die 206. A bonding device 309 may be positioned on the second die pad 208 to form a ball bump 301 on the bonding wire 305.

The bonding device 309 is positioned on the second die pad 208 of the second semiconductor die 206. The bonding device 309 includes a guide element 307 and a capillary element 306. A through hole 303 is formed in the bonding device 309, that is, the guide element 307 and the capillary element 306. After passing the bonding wire 305 through the through hole 303, the ball bump 301 is formed at one end of the bonding wire 305.

The ball bump 301 may be formed by generating an electric discharge, for example, a spark discharge, at one end of the bonding wire 305. The electric discharge may be generated at one end of the bonding wire 305 by using a spark electrode included inside or outside the bonding device 309.

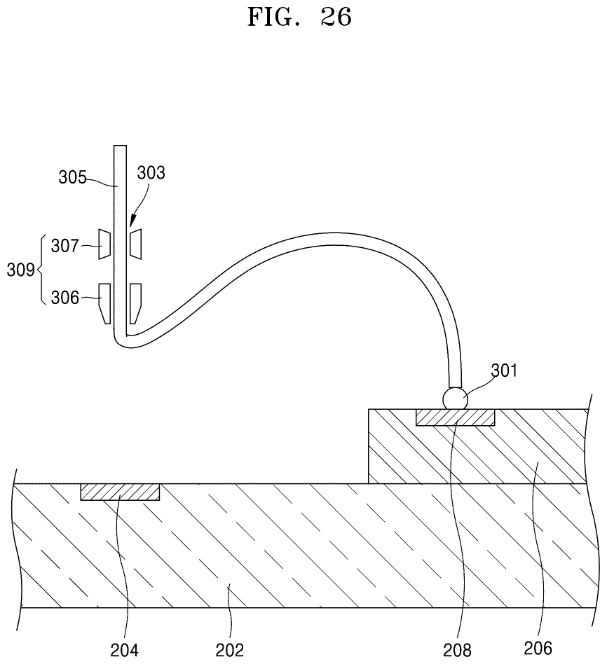

Referring to FIG. 26, after bonding the ball bump 301 on the second die pad 208 of the second semiconductor die 206, the bonding device 309 including the bonding wire 305 is moved to the top of the first die pad 204.

Specifically, the ball bump 301 is first bonded onto the second die pad 208 of the second semiconductor die 206. That is, the bonding device 309 is lowered to bond the ball bump 301 formed at the end of the bonding wire 305 onto the second die pad 208. The ball bump 301 formed at the end of the bonding wire 305 is bonded to the second die pad 208 in a compression method, such as a thermo-compression method. A method of forming the ball bump 301 and then bonding the ball bump 301 may be referred to as a ball bonding method.

If necessary, the bonding wire 305 may be directly bonded to the second die pad 208 without forming a ball bump at the end of the bonding wire 305. A method in which the ball bump is not formed at the end of the bonding wire 305 may be referred to as a stitch bonding method or a wedge bonding method. Subsequently, the bonding device 309 including the bonding wire 305 is moved to the top of the first die pad 204 of the first semiconductor die 202.

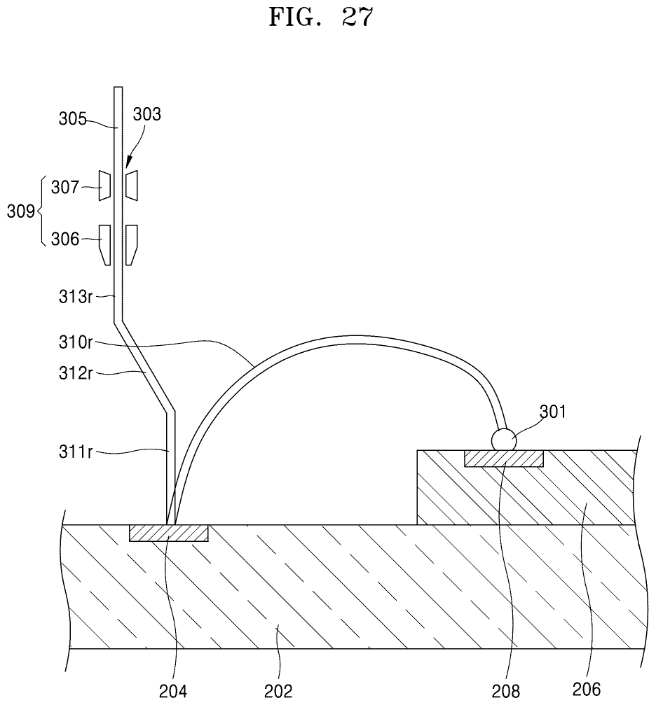

Referring to FIG. 27, the bonding wire 305 is attached onto the first die pad 204 of the first semiconductor die 202. That is, the bonding device 309 is moved and lowered to position the bonding wire 305 on the first die pad 204 of the first semiconductor die 202.

The bonding wire 305 is moved onto the first die pad 204 by using the bonding device 309 and is directly attached to the first die pad 204. The bonding wire 305 may be bonded directly onto the first die pad 204 by a compression method, for example, a thermo-compression method, without forming the ball bump at the end of the bonding wire 305. Accordingly, the bonding wire 305 may form a ring-shaped curved wire component 310r in the horizontal direction from the second die pad 208 to the first die pad 204.

As described above, the method in which the ball bump is not formed at the end of the bonding wire 305 may be referred to as the stitch bonding method. If necessary, a ball bonding method in which the ball bump is formed at the end of the bonding wire 305 and then the bonding wire 305 is bonded onto the first die pad 204 may be used.

Subsequently, the bonding device 309 including the bonding wire 305 is moved upward with respect to the top of the first die pad 204 of the first semiconductor die 202. Subsequently, the bonding device 309 including the bonding wire 305 is continuously moved in an oblique and upward direction with respect to the top of the first die pad 204 of the first semiconductor die 202.

In this case, the bonding wire 305 may include a first upward wire component 311r formed from a surface of the first die pad 204 in the upward direction, an inclined wire component 312r formed from the first upward wire component 311r in an inclined direction, and a second upward wire component 313r formed from the inclined wire component 312r in the upward direction.

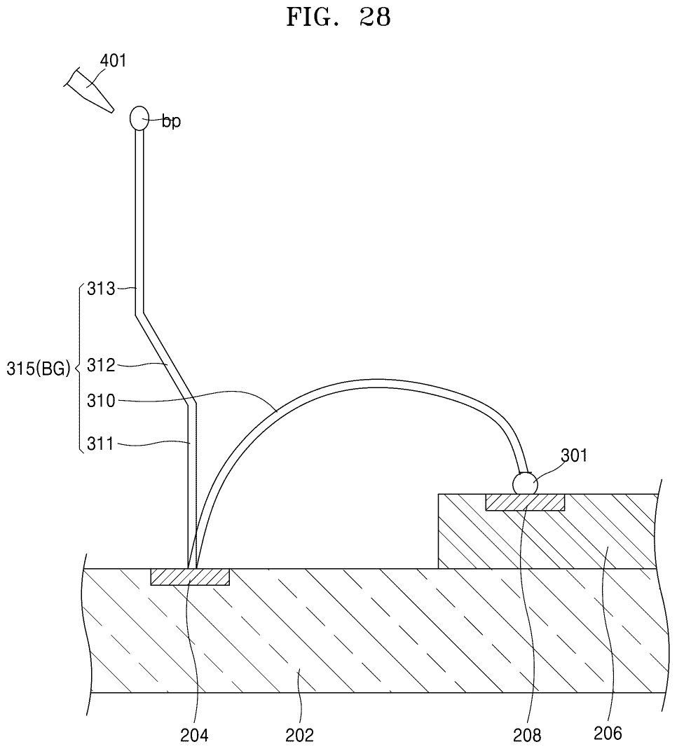

Referring to FIG. 28, after cutting the bonding wire 305 (refer to FIG. 27), the bonding wire 305 (refer to FIG. 27) may be formed into a bonding wire group BG. The bonding wire group BG may include a ring-shaped curved wire 310 extending from the second die pad 208 to the first die pad 204 in the horizontal direction, a first upward wire 311 extending from a surface of the first die pad 204 in the upward direction, an inclined wire 312 extending from the first upward wire 311 in the inclined direction, and a second upward wire 313 extending from the inclined wire 312 in the upward direction. In some embodiments, a spherical ball bp may be formed by generating a spark at one end of the second upward wire 313 by using a spark generating device 401.

While the inventive concept has been particularly shown and described with reference to embodiments thereof, it will be understood that various changes in form and details may be made therein without departing from the spirit and scope of the following claims.

What is claimed is:

1. A semiconductor package comprising:
a lower semiconductor die stack in which a plurality of lower semiconductor dies are stacked vertically in a stepwise manner to extend in a first horizontal direction;
an upper semiconductor die stack in which a plurality of upper semiconductor dies are stacked vertically on the lower semiconductor die stack in a stepwise manner to extend in a first reverse horizontal direction opposite the first horizontal direction;
a wiring structure positioned above the upper semiconductor die stack; and
bonding wire groups connecting the lower semiconductor dies and the upper semiconductor dies to the wiring structure, wherein the bonding wire groups comprise a first bonding wire group connecting a first plurality of semiconductor dies selected from the lower semiconductor dies and the upper semiconductor dies to the wiring structure, and
wherein the first bonding wire group comprises a first bonding portion including a first curved wire connecting a second plurality of semiconductor dies of the first plurality of semiconductor dies, a first upward wire connected to the first curved wire and extending toward the wiring structure, a first inclined wire connected to the first upward wire, and a second upward wire extending toward the wiring structure to connect the first inclined wire to the wiring structure.

2. The semiconductor package of claim 1, wherein the first inclined wire comprises a first sub-inclined wire connected to the first upward wire and a second sub-inclined wire connecting the first sub-inclined wire to the second upward wire.

3. The semiconductor package of claim 1, wherein the first bonding wire group further comprises a second bonding portion including a second curved wire connecting a third plurality of semiconductor dies of the first plurality of semiconductor dies that are not connected by the first bonding portion and a third upward wire extending toward the wiring structure to connect the second curved wire to the wiring structure.

4. The semiconductor package of claim 1, wherein the bonding wire groups further comprise a second bonding wire group connecting a single upper or a single lower semiconductor die selected from the lower semiconductor dies and the upper semiconductor dies to the wiring structure.

5. The semiconductor package of claim 4, wherein the second bonding wire group comprises a fourth upward wire extending toward the wiring structure to connect the single upper or single lower semiconductor die to the wiring structure.

6. The semiconductor package of claim 1, wherein an end of the second upward wire connected to the wiring structure comprises a spherical ball or a h.

7. The semiconductor package of claim 1, wherein the wiring structure comprises a wiring board or a redistribution structure.

8. The semiconductor package of claim 1, wherein a connection solder ball is further formed on the second upward wire and the connection solder ball is connected to the wiring structure.

9. The semiconductor package of claim 1, wherein a first connection point between the first upward wire and the first inclined wire is configured to overlap vertically with some of the upper semiconductor dies.

10. A semiconductor package comprising:
a lower semiconductor die stack in which a plurality of lower semiconductor dies are stacked vertically in a stepwise manner to extend in a first horizontal direction;
an upper semiconductor die stack in which a plurality of upper semiconductor dies are stacked vertically on the lower semiconductor die stack in a stepwise manner to extend in a first reverse horizontal direction opposite to the first horizontal direction;
a wiring structure positioned above the upper semiconductor die stack; and
bonding wire groups connecting the lower semiconductor dies and the upper semiconductor dies to the wiring structure, wherein the bonding wire groups comprise a first bonding wire group comprising bonding wires that connect a first plurality of semiconductor dies selected from the lower semiconductor dies and the upper semiconductor dies to the wiring structure, and a second bonding wire group comprising bonding wires that each connect a single one of the upper or lower semiconductor dies to the wiring structure, wherein the first bonding wire group comprises a first bonding portion including a first curved wire connecting a second plurality of semiconductor dies of the first plurality of semiconductor dies, a first upward wire connected to the first curved wire and extending toward the wiring structure, a first inclined wire connected to the first upward wire, and a second upward wire extending toward the wiring structure to connect the first inclined wire to the wiring structure, and
wherein the bonding wires of the second bonding wire group each comprise a fifth upward wire extending toward the wiring structure to connect the single one of the upper or lower semiconductor dies to the wiring structure.

11. The semiconductor package of claim 10, wherein the first bonding wire group further comprises a second bonding portion including a second curved wire connecting a third plurality semiconductor dies of the first plurality of semiconductor dies that are not connected by the first bonding portion, and a third upward wire extending toward the wiring structure to connect the second curved wire to the wiring structure.

12. The semiconductor package of claim 10, wherein the first bonding wire group further comprises a third bonding portion including a third curved wire connecting a fourth plurality of semiconductor dies of the first plurality of semiconductor dies that are not connected by the first and second bonding portions, and a fourth upward wire extending toward the wiring structure to connect the third curved wire to the wiring structure.

13. The semiconductor package of claim 10, wherein a second connection point between the second upward wire and the first inclined wire is configured not to vertically overlap with the upper semiconductor dies.

14. The semiconductor package of claim 10, wherein each of the lower semiconductor die stack and the upper semiconductor die stack comprises four semiconductor dies.

15. The semiconductor package of claim 10, wherein an end of the second upward wire connected to the wiring structure comprises a spherical ball or a hemispherical ball.

16. A semiconductor package comprising:
a lower semiconductor die stack in which a plurality of lower semiconductor dies are vertically stacked in a stepwise manner to extend in a first horizontal direction;
an upper semiconductor die stack in which a plurality of upper semiconductor dies are vertically stacked on the lower semiconductor die stack in a stepwise manner to extend in a first reverse horizontal direction opposite to the first horizontal direction;
a wiring structure positioned above the upper semiconductor die stack;
a lower bonding wire group connecting the lower semiconductor dies to the wiring structure, wherein the lower bonding wire group comprises a first lower bonding portion including a first lower curved wire connecting at least two of the lower semiconductor dies, a first lower upward wire connected to the first lower curved wire and extending toward the wiring structure, a first lower inclined wire connected to the first lower upward wire, and a second lower upward wire extending toward the wiring structure to connect the first lower inclined wire to the wiring structure; and
an upper bonding wire group electrically connecting the upper semiconductor dies to the wiring structure, wherein the upper bonding wire group comprises a first upper bonding portion including a first upper curved wire connecting at least two of the upper semiconductor dies, and a first upper upward wire extending toward the wiring structure to connect the first upper curved wire to the wiring structure.

17. The semiconductor package of claim 16, wherein the first lower inclined wire comprises a first sub-lower inclined wire connected to the first lower upward wire, and a second sub-lower inclined wire connecting the first sub-lower inclined wire to the second lower upward wire.

18. The semiconductor package of claim 16, wherein the lower bonding wire group further comprises a second lower bonding portion including a second lower curved wire connecting at least two of the lower semiconductor dies that are not connected by the first lower bonding portion, a second lower upward wire connected to the second lower curved wire and extending toward the wiring structure, a second lower inclined wire connected to the second lower upward wire, and a third lower upward wire extending toward the wiring structure to connect the second lower inclined wire to the wiring structure.

19. The semiconductor package of claim 16, wherein the upper bonding wire group comprises a second upper bonding portion including a second upper curved wire connecting at least two of the upper semiconductor dies that are not connected by the first upper bonding portion, and a second upper upward wire extending toward the wiring structure to connect the second upper curved wire to the wiring structure.

20. The semiconductor package of claim 16, wherein each of the lower semiconductor die stack and the upper semiconductor die stack comprises eight semiconductor dies.
